(19) United States
(12) Patent Application Publication
(10) Pub. No.: US 2013/0154123 A1
(43) Pub. Date: Jun. 20, 2013

(54) Semiconductor Device and Fabrication Method

(71) Applicants: Yong Chern Poh, Melaka (MY); Sze Lin Celine Tan, Melaka (MY); Teck Sim Lee, Melaka (MY); Kean Cheong Lee, Melaka (MY); Ralf Otremba, Kaufbeuren (DE); Xaver Schloegel, Sachsenkam (DE); Juergen Schredl, Mering (DE); Josef Hoeglauer, Kirchheim-Heimstetten (DE)

(72) Inventors: Yong Chern Poh, Melaka (MY); Sze Lin Celine Tan, Melaka (MY); Teck Sim Lee, Melaka (MY); Kean Cheong Lee, Melaka (MY); Ralf Otremba, Kaufbeuren (DE); Xaver Schloegel, Sachsenkam (DE); Juergen Schredl, Mering (DE); Josef Hoeglauer, Kirchheim-Heimstetten (DE)

(73) Assignee: INFINEON TECHNOLOGIES AG, Neubiberg (DE)

(21) Appl. No.: 13/330,703

(22) Filed: Dec. 20, 2011

(51) Int. Cl. H01L 23/48; H01L 21/50

(52) U.S. Cl. 257/782; 438/121; 257/E23.01; 257/E21.499

(57) ABSTRACT

In various embodiments, a semiconductor device may include: a carrier; a semiconductor chip disposed over a first side of the carrier; a layer stack disposed between the carrier and the semiconductor chip or over a second side of the carrier opposite the semiconductor chip, or both, the layer stack including at least a first electrically insulating layer, the first electrically insulating layer having a laminate having a first electrically insulating matrix material and a first mechanically stabilizing material embedded in the first electrically insulating matrix material.

### TECHNICAL FIELD

Various embodiments relate generally to a semiconductor device and to a method of fabricating a semiconductor device.

### BACKGROUND

For a semiconductor device it may be desirable to transport away heat generated during operation of the device. Furthermore, it may be desirable to electrically insulate the device from the outside.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a semiconductor device in accordance with an embodiment;

FIG. 1B shows a semiconductor device in accordance with another embodiment;

FIG. 1C shows a semiconductor device in accordance with another embodiment;

FIG. 2A shows a semiconductor device in accordance with another embodiment;

FIG. 2B shows a semiconductor device in accordance with another embodiment;

FIG. 2C shows a semiconductor device in accordance with another embodiment;

FIG. 3A shows a semiconductor device in accordance with another embodiment;

FIG. 3B shows a semiconductor device in accordance with another embodiment;

FIG. 3C shows a semiconductor device in accordance with another embodiment;

FIGS. 4A and 4B show a semiconductor device in accordance with another embodiment;

FIG. 5 shows a semiconductor device in accordance with another embodiment;

FIGS. 6A to 6C show various views illustrating a method of fabricating a semiconductor device in accordance with another embodiment;

FIG. 6D shows a view illustrating a method of fabricating a semiconductor device in accordance with another embodiment;

FIGS. 7A to 7E show various views illustrating a method of fabricating a semiconductor device in accordance with another embodiment;

FIG. 8A shows a multi-insulation-layer stack in accordance with an embodiment;

FIG. 8B shows an electrical insulation including a single electrically insulating layer.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments. The following detailed description therefore is not to be taken in a limiting sense, and the scope of the present invention is defined by the appended claims.

Various embodiments are provided for methods, and various embodiments are provided for devices. It will be understood that basic properties of the methods also hold for the devices and vice versa. Therefore, for sake of brevity, duplicate description of such properties may be omitted.

The terms “at least one” or “one or more” as used herein may be understood to include any integer number equal to or greater than one, i.e. “one”, “two”, “three”, . . . , etc.

The term “a plurality” as used herein may be understood to include any integer number equal to or greater than two, i.e. “two”, “three”, “four”, . . . , etc.

The term “over” as used herein may be understood to include both embodiments where a first layer (structure, element, etc.) is formed (disposed, located, arranged, etc.) on a second layer (structure, element, etc.), with direct physical and/or electrical contact to the second layer (structure, element, etc.), as well as embodiments where a first layer (structure, element, etc.) is in indirect physical and/or electrical contact with a second layer (structure, element, etc.), with one or more intervening layers (structures, elements, etc.) disposed between the first layer (structure, element, etc.) and the second layer (structure, element, etc.).

The terms “coupled” or “connected”, as used herein, may be understood to include both indirect “couplings” or “connections” and direct “couplings” or “connections”.

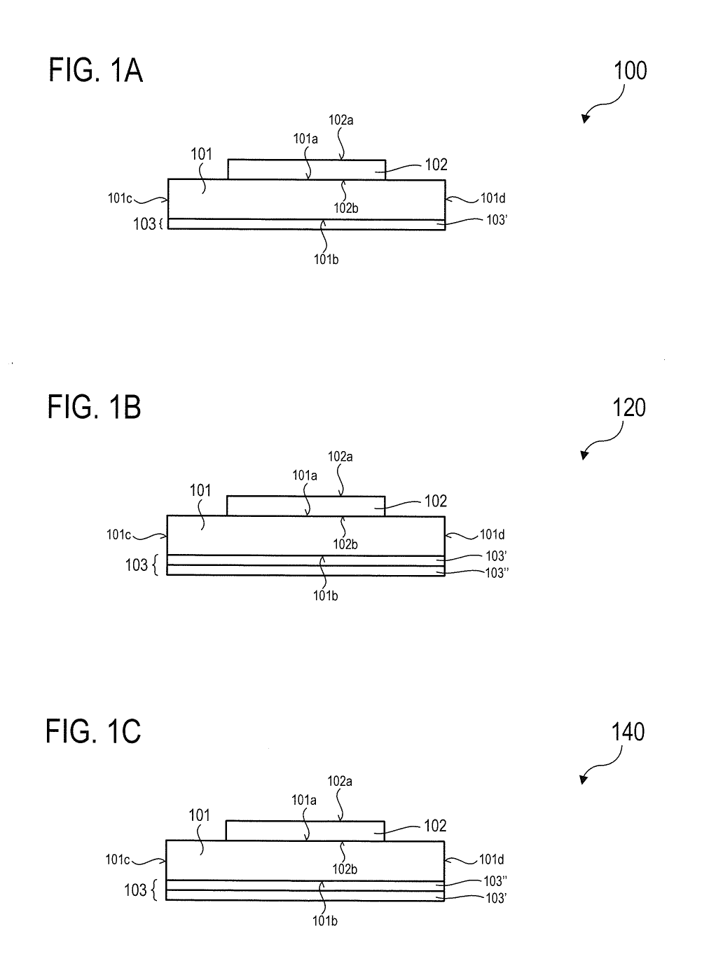

FIG. 1A shows a schematic sectional side view of a semiconductor device 100 in accordance with an embodiment.

The semiconductor device 100 may include a carrier (or carrier element) 101.

The carrier 101 may be of any shape, size or material. In accordance with various embodiments, the carrier 101 may have a first side 101a and a second side 101b, as shown. As shown, the first side 101a and the second side 101b of the carrier 101 may be opposite sides of the carrier 101. The first side 101a of the carrier 101 may, for example, be a front side or top side of the carrier 101 and the second side 101b of the carrier 101 may, for example, be a back side or bottom side of the carrier 101. The carrier 101 may further have sidewalls, e.g. a first sidewall 101c and a second sidewall 101d opposite the first sidewall 101c, as shown, and possibly additional sidewalls not shown in the cross-sectional view.

In accordance with various embodiments, the carrier 101 may include or be made of an electrically conductive material and/or an electrically insulating material.

For example, in accordance with an embodiment, the carrier 101 may include or may be made of a metal, a metal alloy, a dielectric, a plastic, a ceramic or any combination thereof.

For example, in accordance with an embodiment, the carrier 101 may include or may be made of a metal or a metal alloy, for example copper or copper alloys, aluminum or aluminum alloys, or other suitable metals or metal alloys.

In accordance with an embodiment, the carrier 101 may, for example, show a good thermal conductivity. Thus, the carrier 101 may, for example, serve as a heat sink for dissipating heat generated by a semiconductor chip 102 (see below) mounted on the carrier 101.

In accordance with an embodiment, the carrier 101 may have a homogeneous structure, but may also provide internal structures like e.g. conducting paths with an electric redistributional function. Examples for such carriers may include a metal carrier or plate (e.g. a lead frame including one or more die pads and/or pins) or a resin or ceramic substrate including one or more redistribution layers. Alternatively, other suitable carriers may be used.

The semiconductor device 100 may include a semiconductor chip 102 disposed over a first side 101a of the carrier 101. In other words, the semiconductor chip 102 may be mounted on the carrier 101.

In accordance with an embodiment, the semiconductor chip 102 may have a first side 102a and a second side 102b opposite the first side 102a, as shown. The first side 102a may, for example, be a front side (or top side) of the semiconductor chip 102, and the second side 102b may, for example, be a back side (or bottom side) of the semiconductor chip 102.

The semiconductor chip 102 may be of different types and may include, for example, integrated electrical or electro-optical circuits. The semiconductor chip 102 may, for example, include or be configured as a power semiconductor chip, for example as a power transistor such as, for example, a power MOSFET (metal-oxide-semiconductor field effect transistor) or a power IGBT (insulated-gate bipolar transistor), or as a power diode, or as a control circuit, microprocessor or microelectromechanical component, in accordance with some embodiments. In accordance with some embodiments, the semiconductor chip 102 may, for example, have a vertical structure, i.e. the semiconductor chip 102 may be configured in such a way that electric currents can flow in a direction perpendicular to the main surfaces or sides (i.e. the first side 102a and the second side 102b) of the semiconductor chip 102. A semiconductor chip 102 having a vertical structure may, for example, have contact elements on its two main sides, i.e. on the first side 102a (e.g. front side) and the second side 102b (e.g. back side) of the semiconductor chip 102. For example, power transistors and power diodes may have a vertical structure. By way of example, a first source/drain terminal (e.g. a source terminal) and a gate terminal of a power transistor or an anode terminal of a power diode may be located on one of the main sides (e.g. on the first (e.g. front) side 102a), while a second source/drain terminal (e.g. a drain terminal) of the power transistor or the cathode terminal of the power diode may be located on the other one of the main sides (e.g. on the second (e.g. back) side 102b).

The semiconductor chip 102 may include or may be made of any suitable semiconductor material or compound semiconductor material such as, for example, silicon, germanium, silicon-germanium, a ternary semiconductor material or a quaternary semiconductor material. Furthermore, in accordance with some embodiments, it may be possible that the semiconductor chip 102 includes inorganic and/or organic materials that are not semiconductors, such as, for example, insulators, plastics or metals.

In accordance with some embodiments, the semiconductor chip 102 may, for example, have one or more contact elements that may allow electrical contact to be made with the semiconductor chip 102. The contact element(s) may, for example, include or be made of any desired electrically conductive material, for example of a metal, such as e.g. aluminum, gold or copper, a metal alloy or an electrically conductive organic material.

In accordance with some embodiments, the semiconductor chip 102 may, for example, have at least one contact element located on the first side 102a and/or at least one contact element located on the second side 102b.

In accordance with an embodiment, the second side 102b (e.g. back side) of the semiconductor chip 102 may face the first side 101a (e.g. front side) of the carrier 102, as shown.

In accordance with an embodiment, the semiconductor chip 102 may be electrically coupled to the carrier 101, for example by means of an electrical contact element located on the second side 102b of the semiconductor chip 102 (e.g. by means of a back side metallization of the semiconductor chip 102 in accordance with an embodiment) (not shown).

The semiconductor device 100 may further include a layer stack 103 including at least a first electrically insulating layer 103′, as shown. The layer stack 103 may also be referred to as an insulation layer stack herein. Due to the electrically insulating character of the first electrically insulating layer 103′ of the layer stack 103, possible short circuits between the carrier 101 (respectively the semiconductor chip 102) and further elements (not shown) may be avoided in accordance with some embodiments.

In accordance with the embodiment shown, the layer stack 103 may be disposed over a second side 101b of the carrier 101 opposite the semiconductor chip 102.

In accordance with the embodiment shown, the first electrically insulating layer 103′ may be disposed on the second side 101b of the carrier 101.

The first electrically insulating layer 103′ may include or may be a laminate having a first electrically insulating matrix material and a first mechanically stabilizing material embedded in the first electrically insulating matrix material. The first mechanically stabilizing material may also be referred to as first reinforcement material. The first mechanically stabilizing material or reinforcement material may serve to enhance the mechanical stability or strength of the insulation layer stack 103.

The first electrically insulating matrix material and the first mechanically stabilizing material may be different materials.

In accordance with an embodiment, the layer stack 103 may further be disposed over at least parts of the first side 101a of the carrier 101, for example over parts located adjacent to the semiconductor chip 102 (not shown).

In accordance with an embodiment, the layer stack 103 may further be disposed over at least parts of one or more sidewalls of the carrier 101 (not shown). For example, the layer stack 103 may be disposed over the first sidewall 101c of the carrier 101 and/or over the second sidewall 101d of the carrier 101 opposite the first sidewall 101c and/or over one or more additional sidewalls of the carrier 101 (not shown).

In accordance with an embodiment, the first electrically insulating matrix material (of the laminate of the first electrically insulating layer 103′ of the layer stack 103) may include or may be a polymer material, for example an organic polymer material (plastic material), e.g. a resin material such as, for example, epoxy resin. Alternatively or additionally, other suitable electrically insulating materials such as, for example oxides (e.g. a semiconductor oxide such as silicon oxide, or a metal oxide (e.g. alumina)), nitrides (e.g. a semiconductor nitride such as silicon nitride or a metal nitride (e.g. AlN)), a low-k material, or carbon (e.g. diamond) may be used as matrix material in the laminate.

In accordance with an embodiment, the first mechanically stabilizing material (of the laminate of the first electrically insulating layer 103′ of the layer stack 103) may include or may be a fiber material, for example a glass fiber material. Alternatively or additionally, other suitable materials such as, for example oxides (e.g. a semiconductor oxide such as silicon oxide, or a metal oxide (e.g. alumina)), nitrides (e.g. a semiconductor nitride such as silicon nitride or a metal nitride (e.g. AlN)), a low-k material, carbon (e.g. diamond, carbon nanotubes (CNT), graphene), or metal particles (e.g. Cu and/or Fe particles) may be used as mechanically stabilizing material in the laminate. The first mechanically stabilizing material may be an electrically non-conductive material in accordance with some embodiments, or an electrically conductive material in accordance with other embodiments. Electrically conductive materials may generally also be good oder very good heat conductors. Use of an electrically conductive material as first mechanically stabilizing material may thus increase thermal conductivity of the first electrically insulating layer 103′.

In accordance with an embodiment, the laminate of the first electrically insulating layer 103′ may be a fiber reinforced laminate, for example a fiber reinforced plastic laminate in accordance with an embodiment, e.g. a glass fiber reinforced plastic laminate in accordance with an embodiment, for example a glass fiber reinforced epoxy resin laminate in accordance with an embodiment.

In accordance with the embodiment shown, the layer stack 103 may include only the first electrically insulating layer 103′. In accordance with other embodiments, the layer stack 103 may include one or more additional layers, for example one or more additional electrically insulating layers in accordance with some embodiments (not shown, see e.g. FIG. 1B).

In accordance with an embodiment, the first electrically insulating layer 103′ may have a layer thickness in the range from about 1 μm to about 1000 μm, for example in the range from about 5 μm to about 500 μm in accordance with an embodiment, for example in the range from about 10 μm to about 100 μm in accordance with an embodiment, for example a layer thickness of about 50 μm in accordance with an embodiment. In accordance with other embodiments, the layer thickness may have a different value.

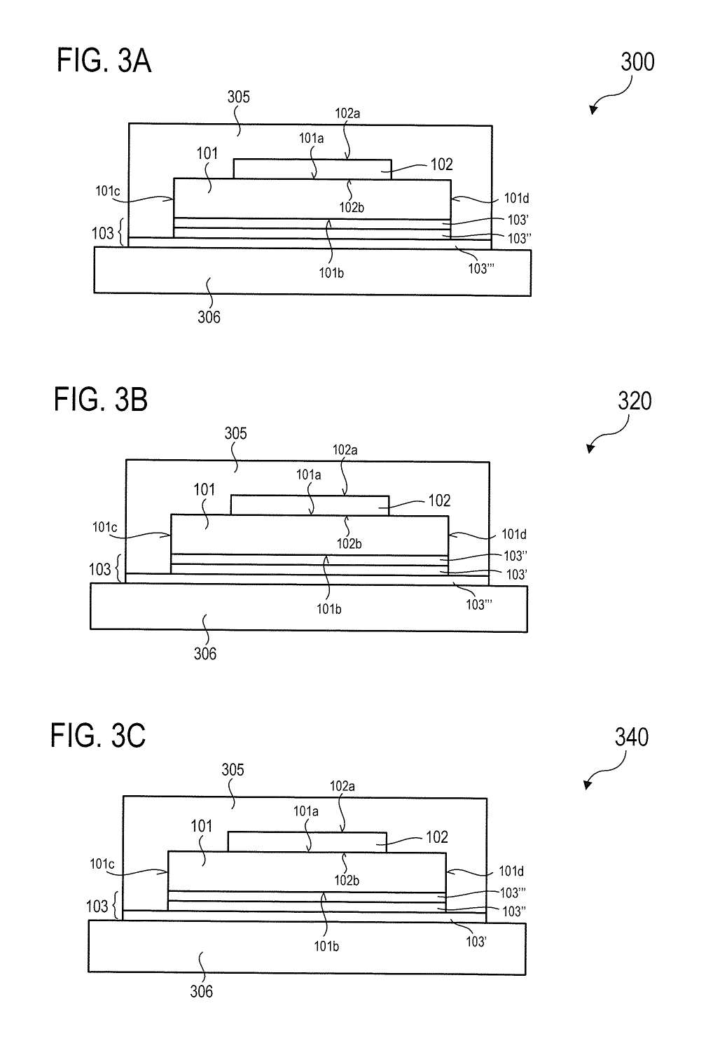

In accordance with an embodiment, the semiconductor device 100 may further include an encapsulation structure (not shown, see e.g. FIG. 3A) that may, for example, serve to protect the semiconductor chip 102 against external influences such as, for example, dirt, humidity or mechanical impact.

In accordance with an embodiment, at least one of the carrier 101, the semiconductor chip 102 and the layer stack 103 may be at least partly covered by the encapsulation structure. In other words, the carrier 101 and/or the semiconductor chip 102 and/or the layer stack 103 may be at least partly covered by the encapsulation structure in accordance with an embodiment.

In accordance with an embodiment, the encapsulation structure may include or may be made of an encapsulation material, for example a mold compound in accordance with an embodiment. The implementation of the mold compound may be arbitrary. In accordance with an embodiment, the mold compound may, for example, include or may be made of a polymer material such as, for example, a resin (e.g. epoxy resin) or silicone. In accordance with other embodiments, the mold compound may include or may be made of other suitable materials, e.g. other suitable moldable materials. The mold compound may not be restricted to be made of a specific material and combinations of different materials may be possible as well. In accordance with other embodiments, the encapsulation material may include or may be another suitable material.

In accordance with an embodiment, the semiconductor device 100 may further include a heat sink (not shown, see e.g. FIG. 3A). The heat sink may be connected to at least one of the carrier 101 and the layer stack 103. For example, the heat sink may be connected to the first electrically insulating layer 103′ of the layer stack 103.

In accordance with an embodiment, the heat sink may include or may be made of a material with a high thermal conductivity, for example a metal or a metal alloy in accordance with an embodiment, alternatively other suitable materials with a high thermal conductivity.

In accordance with some embodiments, the semiconductor device 100 may also be referred to as a module.

During fabrication of the semiconductor device 100, the layer stack 103 may be formed over the second side 101b of the carrier 101, i.e. opposite the first side 101a of the carrier 101, on which the semiconductor chip 102 is mounted or will be mounted. In accordance with an embodiment, the layer stack 103 may be formed after mounting the semiconductor chip 102. Alternatively, the layer stack 103 may be formed before mounting the semiconductor chip 102.

The layer stack 103 may be formed by forming the first electrically insulating layer 103′.

The first electrically insulating layer 103′, more precisely the laminate of the first electrically insulating layer, may be formed by means of any suitable lamination process, e.g. any suitable process to form a reinforced (e.g. fiber reinforced) laminate material, such as, for example, laminating, varnishing, or molding (e.g. injection molding).

FIG. 1B shows a schematic sectional side view of a semiconductor device 120 in accordance with another embodiment. The semiconductor device 120 is different from the semiconductor device 100 of FIG. 1A, in that the semiconductor device 120 includes a layer stack 103 including a plurality of electrically insulating layers 103′, 103″, as will be described further below.

The semiconductor device 120 may include a carrier (or carrier element) 101.

The carrier 101 may be of any shape, size or material. In accordance with various embodiments, the carrier 101 may have a first side 101a and a second side 101b, as shown. As shown, the first side 101a and the second side 101b of the carrier 101 may be opposite sides of the carrier 101. The first side 101a of the carrier 101 may, for example, be a front side or top side of the carrier 101 and the second side 101b of the carrier 101 may, for example, be a back side or bottom side of the carrier 101. The carrier 101 may further have sidewalls, e.g. a first sidewall 101c and a second sidewall 101d opposite the first sidewall 101c, as shown, and possibly additional sidewalls not shown in the cross-sectional view.

In accordance with various embodiments, the carrier 101 may include or be made of an electrically conductive material and/or an electrically insulating material.

For example, in accordance with an embodiment, the carrier 101 may include or be made of a metal, a metal alloy, a dielectric, a plastic, a ceramic or any combination thereof.

For example, in accordance with an embodiment, the carrier 101 may include or may be made of a metal or a metal alloy, for example copper or copper alloys, aluminum or aluminum alloys, or other suitable metals or metal alloys.

In accordance with an embodiment, the carrier 101 may, for example, show a good thermal conductivity. Thus, the carrier 101 may, for example, serve as a heat sink for dissipating heat generated by a semiconductor chip 102 (see below) mounted on the carrier 101.

In accordance with an embodiment, the carrier 101 may have a homogeneous structure, but may also provide internal structures like e.g. conducting paths with an electric redistributional function. Examples for such carriers may include a metal carrier or plate (e.g. a lead frame including one or more die pads and/or pins) or a resin or ceramic substrate including one or more redistribution layers. Alternatively, other suitable carriers may be used.

The semiconductor device 120 may include a semiconductor chip 102 disposed over a first side 101a of the carrier 101. In other words, the semiconductor chip 102 may be mounted on the carrier 101.

In accordance with an embodiment, the semiconductor chip 102 may have a first side 102a and a second side 102b opposite the first side 102a, as shown. The first side 102a may, for example, be a front side (or top side) of the semiconductor chip 102, and the second side 102b may, for example, be a back side (or bottom side) of the semiconductor chip 102.

The semiconductor chip 102 may be of different types and may include, for example, integrated electrical or electro-optical circuits. The semiconductor chip 102 may, for example, include or be configured as a power semiconductor chip, for example as a power transistor such as, for example, a power MOSFET (metal-oxide-semiconductor field effect transistor) or a power IGBT (insulated-gate bipolar transistor), or as a power diode, or as a control circuit, microprocessor or microelectromechanical component, in accordance with some embodiments. In accordance with some embodiments, the semiconductor chip 102 may, for example, have a vertical structure, i.e. the semiconductor chip 102 may be configured in such a way that electric currents can flow in a direction perpendicular to the main surfaces or sides (i.e. the first side 102a and the second side 102b) of the semiconductor chip 102. A semiconductor chip 102 having a vertical structure may, for example, have contact elements on its two main sides, i.e. on the first side 102a (e.g. front side) and the second side 102b (e.g. back side) of the semiconductor chip 102. For example, power transistors and power diodes may have a vertical structure. By way of example, a first source/drain terminal (e.g. a source terminal) and a gate terminal of a power transistor or an anode terminal of a power diode may be located on one of the main sides (e.g. on the first (e.g. front) side 102a), while a second source/drain terminal (e.g. a drain terminal) of the power transistor or the cathode terminal of the power diode may be located on the other one of the main sides (e.g. on the second (e.g. back) side 102b).

The semiconductor chip 102 may include or may be made of any suitable semiconductor material or compound semiconductor material such as, for example, silicon, germanium, silicon-germanium, a ternary semiconductor material or a quaternary semiconductor material. Furthermore, in accordance with some embodiments, it may be possible that the semiconductor chip 102 includes inorganic and/or organic materials that are not semiconductors, such as, for example, insulators, plastics or metals.

In accordance with some embodiments, the semiconductor chip 102 may, for example, have one or more contact elements that may allow electrical contact to be made with the semiconductor chip 102. The contact element(s) may, for example, include or be made of any desired electrically conductive material, for example of a metal, such as e.g. aluminum, gold or copper, a metal alloy or an electrically conductive organic material.

In accordance with some embodiments, the semiconductor chip 102 may, for example, have at least one contact element located on the first side 102a and/or at least one contact element located on the second side 102b.

In accordance with an embodiment, the second side 102b (e.g. back side) of the semiconductor chip 102 may face the first side 101a (e.g. front side) of the carrier 102, as shown.

In accordance with an embodiment, the semiconductor chip 102 may be electrically coupled to the carrier 101, for example by means of an electrical contact element located on the second side 102b of the semiconductor chip 102 (e.g. by means of a back side metallization of the semiconductor chip 102 in accordance with an embodiment) (not shown).

The semiconductor device 120 may further include a layer stack 103 including a plurality of electrically insulating layers 103′, 103″, as shown. The layer stack 103 may also be referred to as an insulation layer stack or multi-insulation-layer stack herein. Due to the electrically insulating character of the electrically insulating layers 103′, 103″ of the layer stack 103, possible short circuits between the carrier 101 (respectively the semiconductor chip 102) and further elements (not shown) may be avoided in accordance with some embodiments.

In accordance with the embodiment shown, the layer stack 103 may be disposed over a second side 101b of the carrier 101 opposite the semiconductor chip 102.

In accordance with the embodiment shown, the layer stack 103 may include a first electrically insulating layer 103′ and a second electrically insulating layer 103″ disposed over the first electrically insulating layer 103′.

In accordance with the embodiment shown, the first electrically insulating layer 103′ may be disposed on the second side 101b of the carrier 101. In accordance with the embodiment shown, the first electrically insulating layer 103′ of the layer stack 103 may be disposed between the carrier 101 and the second electrically insulating layer 103″ of the layer stack 103.

The first electrically insulating layer 103′ may include or may be a laminate having a first electrically insulating matrix material and a first mechanically stabilizing material embedded in the first electrically insulating matrix material. The first mechanically stabilizing material may also be referred to as first reinforcement material. The first mechanically stabilizing material or reinforcement material may serve to enhance the mechanical stability or strength of the insulation layer stack 103.

The first electrically insulating matrix material and the first mechanically stabilizing material may be different materials.

In accordance with an embodiment, the second electrically insulating layer 103″ may include or may be made of an organic insulating material, for example an organic polymer material (plastic material) such as e.g. a duroplast material, an imide material, or a resin material (e.g. epoxy resin)). In this case, the second electrically insulating layer may, for example, be formed by means of any suitable process for forming an organic insulating layer.

In accordance with another embodiment, the second electrically insulating layer 103″ may include or may be made of an oxide material, for example a metal oxide (e.g. aluminum oxide (alumina) or copper oxide) or a semiconductor oxide (e.g. silicon oxide), or a nitride material, for example a metal nitride (e.g. aluminum nitride) or a semiconductor nitride (e.g. silicon nitride). In this case, the second electrically insulating layer may, for example, be formed by means of any suitable process (e.g. deposition process) for forming an oxide layer or oxide-containing layer, or a nitride layer or nitride-containing layer.

In accordance with another embodiment, the second electrically insulating layer 103″ may include or may be made of a low-k material. In this case, the second electrically insulating layer may, for example, be formed by means of any suitable process for forming a low-k material.

In accordance with another embodiment, the second electrically insulating layer 103″ may include or may be made of diamond. In this case, the second electrically insulating layer may, for example, be formed by means of any suitable process for forming a diamond layer or diamond-containing layer.

In accordance with an embodiment, the second electrically insulating layer 103″ may include or may be a laminate having a second electrically insulating matrix material and a second mechanically stabilizing material embedded in the second electrically insulating matrix material. The second mechanically stabilizing material may also be referred to as second reinforcement material. The second mechanically stabilizing material or reinforcement material may serve to enhance the mechanical stability or strength of the insulation layer stack 103.

The second electrically insulating matrix material and the second mechanically stabilizing material may be different materials.

In accordance with an embodiment, the layer stack 103 may further be disposed over at least parts of the first side 101a of the carrier 101, for example over parts located adjacent to the semiconductor chip 102 (not shown).

In accordance with an embodiment, the layer stack 103 may further be disposed over at least parts of one or more sidewalls of the carrier 101 (not shown). For example, the layer stack 103 may be disposed over the first sidewall 101c of the carrier 101 and/or over the second sidewall 101d of the carrier 101 opposite the first sidewall 101c and/or over one or more additional sidewalls of the carrier 101 (not shown).

In accordance with an embodiment, the first electrically insulating matrix material (of the laminate of the first electrically insulating layer 103′ of the layer stack 103) may include or may be a polymer material, for example an organic polymer material (plastic material), e.g. a resin material such as, for example, epoxy resin. Alternatively or additionally, other suitable electrically insulating materials such as, for example oxides (e.g. a semiconductor oxide such as silicon oxide, or a metal oxide (e.g. alumina)), nitrides (e.g. a semiconductor nitride such as silicon nitride, or a metal nitride (e.g. aluminum nitride (AlN)), a low-k material, or carbon (e.g. diamond) may be used as matrix material in the laminate.

In accordance with an embodiment, the second electrically insulating matrix material (of the laminate of the second electrically insulating layer 103″ of the layer stack 103) may include or may be a polymer material, for example an organic polymer material (plastic material), e.g. a resin material such as, for example, epoxy resin. Alternatively or additionally, other suitable electrically insulating materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, or carbon (e.g. diamond) may be used as matrix material in the laminate.

In accordance with an embodiment, the first electrically insulating matrix material and the second electrically insulating matrix material may include or may be the same material. Alternatively, the first electrically insulating matrix material and the second electrically insulating matrix material may include or may be different materials.

In accordance with an embodiment, the first mechanically stabilizing material (of the laminate of the first electrically insulating layer 103′ of the layer stack 103) may include or may be a fiber material, for example a glass fiber material. Alternatively or additionally, other suitable materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles) may be used as mechanically stabilizing material in the laminate. The first mechanically stabilizing material may be an electrically non-conductive material in accordance with some embodiments, or an electrically conductive material in accordance with other embodiments. Electrically conductive materials may generally also be good oder very good heat conductors. Use of an electrically conductive material as first mechanically stabilizing material may thus increase thermal conductivity of the first electrically insulating layer 103′.

In accordance with an embodiment, the laminate of the first electrically insulating layer 103′ may be a fiber reinforced laminate, for example a fiber reinforced plastic laminate in accordance with an embodiment, e.g. a glass fiber reinforced plastic laminate in accordance with an embodiment, for example a glass fiber reinforced epoxy resin laminate in accordance with an embodiment.

In accordance with an embodiment, the second mechanically stabilizing material (of the laminate of the second electrically insulating layer 103″ of the layer stack 103) may include or may be a fiber material, for example a glass fiber material. Alternatively or additionally, other suitable materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles) may be used as mechanically stabilizing material in the laminate. The second mechanically stabilizing material may be an electrically non-conductive material in accordance with some embodiments, or an electrically conductive material in accordance with other embodiments. Electrically conductive materials may generally also be good oder very good heat conductors. Use of an electrically conductive material as second mechanically stabilizing material may thus increase thermal conductivity of the second electrically insulating layer 103″.

In accordance with an embodiment, the first mechanically stabilizing material and the second mechanically stabilizing material may include or may be the same material. Alternatively, the first mechanically stabilizing material and the second mechanically stabilizing material may include or may be different materials.

In accordance with an embodiment, the laminate of the second electrically insulating layer 103″ may be a fiber reinforced laminate, for example a fiber reinforced plastic laminate in accordance with an embodiment, e.g. a glass fiber reinforced plastic laminate in accordance with an embodiment, for example a glass fiber reinforced epoxy resin laminate in accordance with an embodiment.

In accordance with an embodiment, the first electrically insulating layer 103′ of the layer stack 103 may have a layer thickness in the range from about 1 μm to about 1000 μm, for example in the range from about 5 μm to about 500 μm in accordance with an embodiment, for example in the range from about 10 μm to about 100 μm in accordance with an embodiment, for example a layer thickness of about 50 μm in accordance with an embodiment. In accordance with other embodiments, the layer thickness may have a different value.

In accordance with an embodiment, the second electrically insulating layer 103″ of the layer stack 103 may have a layer thickness in the range from about 1 μm to about 1000 μm, for example in the range from about 5 μm to about 500 μm in accordance with an embodiment, for example in the range from about 10 μm to about 100 μm in accordance with an embodiment, for example a layer thickness of about 50 μm in accordance with an embodiment. In accordance with other embodiments, the layer thickness may have a different value.

In accordance with an embodiment, the layer stack 103 may include one or more additional electrically insulating layers (not shown), for example a third electrically insulating layer disposed over the second electrically insulating layer 103″ in accordance with an embodiment, a fourth electrically insulating layer disposed over the third electrically insulating layer in accordance with an embodiment, a fifth electrically insulating layer disposed over the fourth electrically insulating layer in accordance with an embodiment, . . . , etc.

In general, the layer stack 103 may have any number of electrically insulating layers equal to or greater than two. For example, in accordance with an embodiment, the number of electrically insulating layers in the layer stack 103 may be in the range from two to ten, for example in the range from two to five in accordance with an embodiment. In accordance with other embodiments, the number of electrically insulating layers may be different.

The additional electrically insulating layer(s) may be configured in a similar manner as the first electrically insulating layer 103′ and/or the second electrically insulating layer 103″.

For example, in accordance with an embodiment one or more of the additional electrically insulating layer(s) may include or may be made of an organic insulating material, for example an organic polymer material (plastic material) such as e.g. a duroplast material, an imide material, or a resin material (e.g. epoxy resin)).

In accordance with another embodiment, one or more of the additional electrically insulating layer(s) may include or may be made of an oxide material, for example a metal oxide (e.g. aluminum oxide (alumina) or copper oxide) or a semiconductor oxide (e.g. silicon oxide), or a nitride material, for example a metal nitride (e.g. aluminum nitride) or a semiconductor nitride (e.g. silicon nitride).

In accordance with still another embodiment, one or more of the additional electrically insulating layer(s) may include or may be made of a low-k material.

In accordance with still another embodiment, one or more of the additional electrically insulating layer(s) may include or may be made of diamond.

In accordance with still another embodiment, one or more of the additional electrically insulating layer(s) may include or be a laminate having an electrically insulating matrix material and a mechanically stabilizing material (reinforcement material) embedded in the electrically insulating matrix material.

The (respective) electrically insulating matrix material(s) of the additional electrically insulating layer(s) and the (respective) mechanically stabilizing material(s) of the additional electrically insulating layer(s) may be different materials.

In accordance with an embodiment, the (respective) electrically insulating matrix material(s) (of the laminate(s) of the additional electrically insulating layer(s) of the layer stack) may include or may be a polymer material, for example an organic polymer material (plastic material), e.g. a resin material such as, for example, epoxy resin. Alternatively or additionally, other suitable electrically insulating materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, or carbon (e.g. diamond) may be used as matrix material(s) in the laminate(s).

In accordance with an embodiment, the electrically insulating matrix material(s) of the laminate(s) of one or more of the additional electrically insulating layers may be the same as the first electrically insulating matrix material (of the laminate of the first electrically insulating layer 103′ of the layer stack 103) and/or as the second electrically insulating matrix material (of the laminate of the second electrically insulating layer 103″ of the layer stack 103).

In accordance with an embodiment, the electrically insulating matrix material in each additional electrically insulating layer may be the same. Alternatively, the electrically insulating matrix materials of the additional electrically insulating layers may be different.

In accordance with an embodiment, the (respective) mechanically stabilizing material(s) (of the laminate(s) of the additional electrically insulating layer(s) of the layer stack 103) may include or may be a fiber material, for example a glass fiber material. Alternatively or additionally, other suitable materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles) may be used as mechanically stabilizing material(s) in the laminate(s). The (respective) mechanically stabilizing material(s) may be an electrically non-conductive material in accordance with some embodiments, or an electrically conductive material in accordance with other embodiments. Electrically conductive materials may generally also be good oder very good heat conductors. Use of an electrically conductive material as mechanically stabilizing material may thus increase thermal conductivity of the additional electrically insulating layer(s).

In accordance with an embodiment, the mechanically stabilizing material in each additional electrically insulating layer may be the same. Alternatively, the mechanically stabilizing materials of the additional electrically insulating layers may be different.

In accordance with an embodiment, the laminate of each additional electrically insulating layer may be a fiber reinforced laminate, for example a fiber reinforced plastic laminate in accordance with an embodiment, e.g. a glass fiber reinforced plastic laminate in accordance with an embodiment, for example a glass fiber reinforced epoxy resin laminate in accordance with an embodiment.

In accordance with an embodiment, at least one of the additional electrically insulating layers of the layer stack 103 may have a layer thickness in the range from about 1 μm to about 1000 μm, for example in the range from about 5 μm to about 500 μm in accordance with an embodiment, for example in the range from about 10 μm to about 100 μm in accordance with an embodiment, for example a layer thickness of about 50 μm in accordance with an embodiment. In accordance with other embodiments, the layer thickness may have a different value.

In accordance with an embodiment, the layer stack may 103 have a total layer thickness in the range from about 2 μm to about 10000 μm, for example in the range from about 10 μm to about 5000 μm in accordance with an embodiment, for example in the range from about 20 μm to about 1000 μm in accordance with an embodiment, for example in the range from about 100 μm μm to 500 μm about in accordance with an embodiment. Alternatively, the total layer thickness may have a different value. In accordance with an embodiment, the total layer thickness may be the sum of the layer thicknesses of the individual electrically insulating layers (i.e. the first electrically insulating layer 103′, the second electrically insulating layer 103″ and possibly additional electrically insulating layers) of the layer stack 103.

In accordance with an embodiment, the semiconductor device 120 may further include an encapsulation structure (not shown, see e.g. FIG. 3A) that may, for example, serve to protect the semiconductor chip 102 against external influences such as, for example, dirt, humidity or mechanical impact.

In accordance with an embodiment, at least one of the carrier 101, the semiconductor chip 102 and the layer stack 103 may be at least partly covered by the encapsulation structure. In other words, the carrier 101 and/or the semiconductor chip 102 and/or the layer stack 103 may be at least partly covered by the encapsulation structure in accordance with an embodiment.

In accordance with an embodiment, the encapsulation structure may include or may be made of an encapsulation material, for example a mold compound in accordance with an embodiment. The implementation of the mold compound may be arbitrary. In accordance with an embodiment, the mold compound may, for example, include or may be made of a polymer material such as, for example, a resin (e.g. epoxy resin) or silicone. In accordance with other embodiments, the mold compound may include or may be made of other suitable materials, e.g. other suitable moldable materials. The mold compound may not be restricted to be made of a specific material and combinations of different materials may be possible as well. In accordance with other embodiments, the encapsulation material may include or may be another suitable material.

In accordance with an embodiment, the semiconductor device 120 may further include a heat sink (not shown, see e.g. FIG. 3A). The heat sink may be connected to at least one of the carrier 101 and the layer stack 103. For example, in accordance with an embodiment, the heat sink may be connected to the second electrically insulating layer 103″ (in general, to the outermost electrically insulating layer) of the layer stack 103.

In accordance with an embodiment, the heat sink may include or may be made of a material with a high thermal conductivity, for example a metal or a metal alloy in accordance with an embodiment, alternatively other suitable materials with a high thermal conductivity.

In accordance with some embodiments, the semiconductor device 120 may also be referred to as a module.

During fabrication of the semiconductor device 120, the layer stack 103 may be formed over the second side 101b of the carrier 101, i.e. opposite the first side 101a of the carrier 101, on which the semiconductor chip 102 is mounted or will be mounted. In accordance with an embodiment, the layer stack 103 may be formed after mounting the semiconductor chip 102. Alternatively, the layer stack 103 may be formed before mounting the semiconductor chip 102.

The layer stack 103 may be formed by subsequently forming the individual electrically insulating layers (i.e. the first electrically insulating layer 103′ and the second electrically insulating layer 103″, and possibly additional electrically insulating layers (not shown) in accordance with some embodiments) one over the other.

Each of the electrically insulating layers of the layer stack 103, more precisely the laminate of each of the electrically insulating layers, may be formed by means of any suitable lamination process, e.g. any suitable process to form a reinforced (e.g. fiber reinforced) laminate material, such as, for example, laminating, varnishing, or molding (e.g. injection molding).

The electrically insulating layers of the layer stack 103 may be formed in separate process steps that may, for example, be separated in time. For example, a certain time period may elapse between the formation of two consecutive layers of the stack 103 in accordance with an embodiment. Thus, even in case that two adjacent electrically insulating layers of the layer stack 103 are made of the same materials, it may be possible to distinguish the two layers from one another in accordance with various embodiments. For example, a distinct interface may be seen at the location where the surfaces of the two layers meet in accordance with various embodiments. At the interface, each of the two adjacent layers may have surface properties instead of bulk properties. For example, at the interface each of the two adjacent layers may exhibit a molecular or atomic arrangement that is characteristic for its surface (instead of a molecular or atomic arrangement that is characteristic for its bulk). Illustratively, by forming a plurality of distinct electrically insulating layers (instead of a single contiguous layer), an electrical insulation having one or more predetermined “breaking points” (i.e. interfaces where the bulk structure may clearly be interrupted) may be generated, as will, for example, be described in further detail herein below in connection with FIG. 8A.

FIG. 1C shows a schematic sectional side view of a semiconductor device 140 in accordance with another embodiment.

The semiconductor device 140 is to some extent similar to the semiconductor device 120 shown in FIG. 1B. In particular, the same reference numerals denote the same elements as there and will not be described again here in detail for sake of brevity.

The semiconductor device 140 is different from the semiconductor device 120, in that the second electrically insulating layer 103″ of the layer stack 103 in the semiconductor device 140 is disposed between the carrier 101 and the first electrically insulating layer 103′ of the layer stack 103. In other words, the sequence of the electrically insulating layers 103′, 103″ is reversed compared to that in FIG. 1B.

As will be readily understood, the layer stack 103 of the semiconductor device 140 may include additional (e.g. electrically insulating) layers, which may, for example, be configured in a similar or the same manner as the first and/or second electrically insulating layer 103′, 103″.

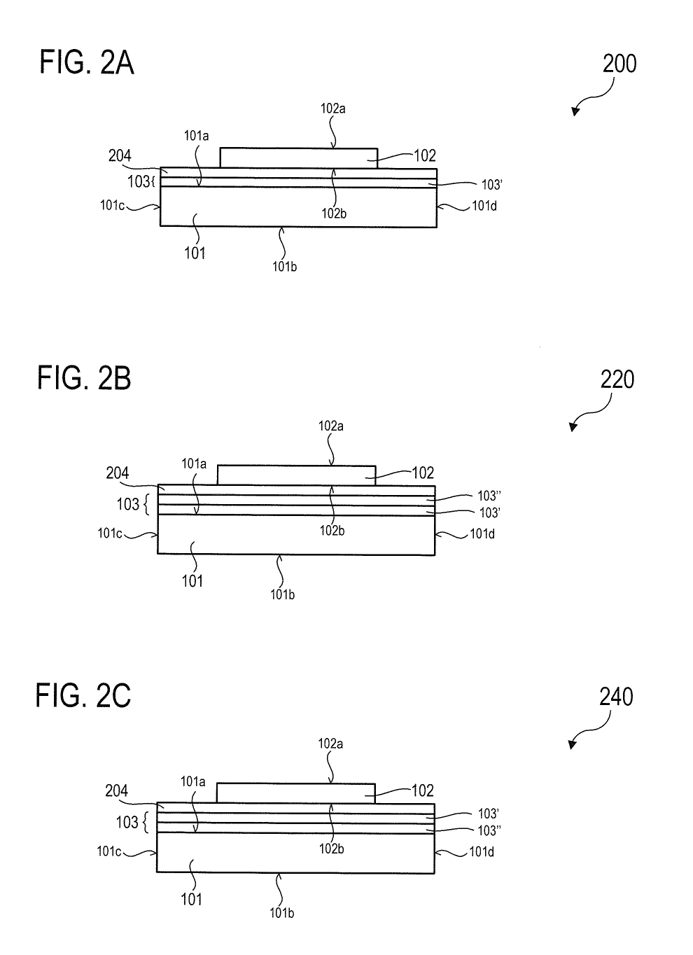

FIG. 2A shows a schematic sectional side view of a semiconductor device 200 in accordance with another embodiment.

The semiconductor device 200 may include a carrier (or carrier element) 101. The carrier 101 may have a first side 101a and a second side 101b. As shown, the first side 101a and the second side 101b of the carrier 101 may be opposite sides of the carrier 101. The first side 101a of the carrier 101 may, for example, be a front side or top side of the carrier 101 and the second side 101b of the carrier 101 may, for example, be a back side or bottom side of the carrier 101. The carrier 101 may further have sidewalls, e.g. a first sidewall 101c and a second sidewall 101d opposite the first sidewall 101c, as shown, and possibly additional sidewalls not shown in the cross-sectional view.

The carrier 101 may include or be made of an electrically conductive material and/or an electrically insulating material.

For example, in accordance with an embodiment, the carrier 101 may include or be made of a metal, an alloy, a dielectric, a plastic, a ceramic or any combination thereof. In accordance with an embodiment, the carrier 101 may, for example, show a good thermal conductivity. In accordance with an embodiment, the carrier 101 may have a homogeneous structure, but may also provide internal structures like e.g. conducting paths with an electric redistributional function. Examples for such carriers may include include a metal carrier or plate (e.g. a lead frame including one or more die pads and/or pins) or a resin or ceramic substrate including one or more redistribution layers. Alternatively, other suitable carriers may be used.

The semiconductor device 200 may include a semiconductor chip 102 disposed over a first side 101a of the carrier 101. In other words, the semiconductor chip 102 may be mounted on the carrier 101. As shown, a layer stack 103 including a plurality of electrically insulating layers 103′, 103″ may be disposed between the first side 101a of the carrier 101 and the semiconductor chip 102, as will be explained in more detail further below. In accordance with an embodiment and as shown, an electrically conductive layer 204 may be disposed between the layer stack 103 and the semiconductor chip 102, as will be explained in more detail further below.

In accordance with an embodiment, the semiconductor chip 102 may have a first side 102a and a second side 102b opposite the first side 102a, as shown. The first side 102a may, for example, be a front side (or top side) of the semiconductor chip 102, and the second side 102b may, for example, be a back side (or bottom side) of the semiconductor chip 102.

The semiconductor chip 102 may be of different types and may include, for example, integrated electrical or electro-optical circuits. The semiconductor chip 102 may, for example, include or be configured as a power semiconductor chip, for example as a power transistor such as, for example, a power MOSFET (metal-oxide-semiconductor field effect transistor) or a power IGBT (insulated-gate bipolar transistor), or as a power diode, or as a control circuit, microprocessor or microelectromechanical component, in accordance with some embodiments. In accordance with some embodiments, the semiconductor chip 102 may, for example, have a vertical structure, i.e. the semiconductor chip 102 may be configured in such a way that electric currents can flow in a direction perpendicular to the main surfaces or sides (i.e. the first side 102a and the second side 102b) of the semiconductor chip 102. A semiconductor chip 102 having a vertical structure may, for example, have contact elements on its two main sides, i.e. on the first side 102a (e.g. front side) and the second side 102b (e.g. back side) of the semiconductor chip 102. For example, power transistors and power diodes may have a vertical structure. By way of example, a first source/drain terminal (e.g. a source terminal) and a gate terminal of a power transistor or an anode terminal of a power diode may be located on one of the main sides (e.g. on the first (e.g. front) side 102a), while a second source/drain terminal (e.g. a drain terminal) of the power transistor or the cathode terminal of the power diode may be located on the other one of the main sides (e.g. on the second (e.g. back) side 102b).

The semiconductor chip 102 may include or may be made of any suitable semiconductor material or compound semiconductor material such as, for example, silicon, germanium, silicon-germanium, a ternary semiconductor material or a quaternary semiconductor material. Furthermore, in accordance with some embodiments, it may be possible that the semiconductor chip 102 includes inorganic and/or organic materials that are not semiconductors, such as, for example, insulators, plastics or metals.

In accordance with some embodiments, the semiconductor chip 102 may, for example, have one or more contact elements that may allow electrical contact to be made with the semiconductor chip 102. The contact element(s) may, for example, include or be made of any desired electrically conductive material, for example of a metal, such aluminum, gold or copper, a metal alloy or an electrically conductive organic material.

In accordance with some embodiments, the semiconductor chip 102 may, for example, have at least one contact element located on the first side 102a and/or at least one contact element located on the second side 102b.

The semiconductor device 200 may include a layer stack 103 including at least a first electrically insulating layer 103′, as shown. The layer stack 103 may also be referred to as an insulation layer stack.

In accordance with the embodiment shown, the layer stack 103 may be disposed over the first side 101a of the carrier 101 between the carrier 101 and the semiconductor chip 102.

Due to the electrically insulating character of the electrically insulating layer 103′, possible short circuits between the semiconductor chip 102 and further elements (not shown) may be avoided in accordance with some embodiments.

In accordance with the embodiment shown, the first electrically insulating layer 103′ may be disposed on the first side 101a of the carrier 101.

The first electrically insulating layer 103′ may include or may be a laminate having a first electrically insulating matrix material and a first mechanically stabilizing material embedded in the first electrically insulating matrix material. The first mechanically stabilizing material may also be referred to as first reinforcement material.

The first electrically insulating matrix material and the first mechanically stabilizing material may be different materials.

In accordance with an embodiment, the layer stack 103 may further be disposed over at least parts of the second side 101b of the carrier 101 (not shown).

In accordance with an embodiment, the layer stack 103 may further be disposed over at least parts of one or more sidewalls of the carrier 101 (not shown). For example, the layer stack 103 may be disposed over the first sidewall 101c of the carrier 101 and/or over the second sidewall 101d of the carrier 101 opposite the first sidewall 101c and/or over one or more additional sidewalls of the carrier 101 (not shown).

In accordance with an embodiment, the first electrically insulating matrix material (of the laminate of the first electrically insulating layer 103′ of the layer stack 103) may include or may be a polymer material, for example an organic polymer material (plastic material), e.g. a resin material such as, for example, epoxy resin. Alternatively or additionally, other suitable electrically insulating materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, or carbon (e.g. diamond) may be used as matrix material in the laminate.

In accordance with an embodiment, the first mechanically stabilizing material (of the laminate of the first electrically insulating layer 103′ of the layer stack 103) may include or may be a fiber material, for example a glass fiber material. Alternatively or additionally, other suitable materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles) may be used as mechanically stabilizing material in the laminate. The first mechanically stabilizing material may be an electrically non-conductive material in accordance with some embodiments, or an electrically conductive material in accordance with other embodiments. Electrically conductive materials may generally also be good oder very good heat conductors. Use of an electrically conductive material as first mechanically stabilizing material may thus increase thermal conductivity of the first electrically insulating layer 103′.

In accordance with an embodiment, the laminate of the first electrically insulating layer 103′ may be a fiber reinforced laminate, for example a fiber reinforced plastic laminate in accordance with an embodiment, e.g. a glass fiber reinforced plastic laminate in accordance with an embodiment, for example a glass fiber reinforced epoxy resin laminate in accordance with an embodiment.

In accordance with the embodiment shown, the layer stack 103 may include only the first electrically insulating layer 103′. In accordance with other embodiments, the layer stack 103 may include one or more additional layers, for example one or more additional electrically insulating layers in accordance with some embodiments (not shown, see e.g. FIG. 2B).

In accordance with an embodiment, the first electrically insulating layer 103′ may have a layer thickness in the range from about 1 μm to about 1000 μm, for example in the range from about 5 μm to about 500 μm in accordance with an embodiment, for example in the range from about 10 μm to about 100 μm in accordance with an embodiment, for example a layer thickness of about 50 μm in accordance with an embodiment. In accordance with other embodiments, the layer thickness may have a different value.

In accordance with an embodiment, an electrically conductive layer 204 may be disposed between the layer stack 103 and the semiconductor chip 102.

In accordance with an embodiment, the second side 102b (e.g. back side) of the semiconductor chip 102 may face the electrically conductive layer 204.

In accordance with an embodiment, the semiconductor chip 102 may be electrically coupled to the electrically conductive layer 204, for example by means of an electrical contact element disposed on the second side 102b of the semiconductor chip 102 (e.g. by means of a back side metallization of the semiconductor chip 102 in accordance with an embodiment) (not shown). Thus, the electrically conductive layer 204 may serve to electrically contact the semiconductor chip 102.

In accordance with an embodiment, the semiconductor device 200 may further include an encapsulation structure (not shown, see e.g. FIG. 3A) that may, for example, serve to protect the semiconductor chip 102 against external influences such as, for example, dirt, humidity or mechanical impact.

In accordance with an embodiment, at least one of the carrier 101, the semiconductor chip 102 and the layer stack 103 may be at least partly covered by the encapsulation structure. In other words, the carrier 101 and/or the semiconductor chip 102 and/or the layer stack 103 may be at least partly covered by the encapsulation structure in accordance with an embodiment.

In accordance with an embodiment, the encapsulation structure may include or may be made of an encapsulation material, for example a mold compound in accordance with an embodiment. The implementation of the mold compound may be arbitrary. In accordance with an embodiment, the mold compound may, for example, include or may be made of a polymer material such as, for example, a resin (e.g. epoxy resin) or silicone. In accordance with other embodiments, the mold compound may include or may be made of other suitable materials, e.g. other suitable moldable materials. The mold compound may not be restricted to be made of a specific material and combinations of different materials may be possible as well. In accordance with other embodiments, the encapsulation material may include or may be another suitable material.

In accordance with an embodiment, the semiconductor device 200 may further include a heat sink (not shown). The heat sink may be coupled to at least one of the carrier 101 and the layer stack 103. For example, in accordance with an embodiment, the heat sink may be coupled to the second side 101b of the carrier 101.

In accordance with an embodiment, the heat sink may include or may be made of a material with a high thermal conductivity, for example a metal or a metal alloy in accordance with an embodiment, alternatively other suitable materials with a high thermal conductivity.

In accordance with some embodiments, the semiconductor device 200 may also be referred to as a module.

During fabrication of the semiconductor device 200, the layer stack 103 may be formed over the first side 101a of the carrier 101. The layer stack 103 may be formed before mounting the semiconductor chip 102.

The layer stack 103 may be formed by forming the first electrically insulating layer 103′, and possibly additional electrically insulating layers (not shown) in accordance with some embodiments).

The first electrically insulating layer 103′ of the layer stack 103, more precisely the laminate of the first electrically insulating layer 103′, may be formed by means of any suitable lamination process, e.g. any suitable process to form a reinforced (e.g. fiber reinforced) laminate material, such as, for example, laminating, varnishing, or molding (e.g. injection molding).

FIG. 2B shows a schematic sectional side view of a semiconductor device 220 in accordance with another embodiment. The semiconductor device 220 is different from the semiconductor device 200 of FIG. 2A, in that the semiconductor device 220 includes a layer stack 103 including a plurality of electrically insulating layers 103′, 103″, as will be described further below.

The semiconductor device 220 may include a carrier (or carrier element) 101. The carrier 101 may have a first side 101a and a second side 101b. As shown, the first side 101a and the second side 101b of the carrier 101 may be opposite sides of the carrier 101. The first side 101a of the carrier 101 may, for example, be a front side or top side of the carrier 101 and the second side 101b of the carrier 101 may, for example, be a back side or bottom side of the carrier 101. The carrier 101 may further have sidewalls, e.g. a first sidewall 101c and a second sidewall 101d opposite the first sidewall 101c, as shown, and possibly additional sidewalls not shown in the cross-sectional view.

The carrier 101 may include or be made of an electrically conductive material and/or an electrically insulating material.

For example, in accordance with an embodiment, the carrier 101 may include or be made of a metal, an alloy, a dielectric, a plastic, a ceramic or any combination thereof. In accordance with an embodiment, the carrier 101 may, for example, show a good thermal conductivity. In accordance with an embodiment, the carrier 101 may have a homogeneous structure, but may also provide internal structures like e.g. conducting paths with an electric redistributional function. Examples for such carriers may include a metal carrier or plate (e.g. a lead frame including one or more die pads and/or pins) or a resin or ceramic substrate including one or more redistribution layers. Alternatively, other suitable carriers may be used.

The semiconductor device 220 may include a semiconductor chip 102 disposed over a first side 101a of the carrier 101. In other words, the semiconductor chip 102 may be mounted on the carrier 101. As shown, a layer stack 103 including a plurality of electrically insulating layers 103′, 103″ may be disposed between the first side 101a of the carrier 101 and the semiconductor chip 102, as will be explained in more detail further below. In accordance with an embodiment and as shown, an electrically conductive layer 204 may be disposed between the layer stack 103 and the semiconductor chip 102, as will be explained in more detail further below.

In accordance with an embodiment, the semiconductor chip 102 may have a first side 102a and a second side 102b opposite the first side 102a, as shown. The first side 102a may, for example, be a front side (or top side) of the semiconductor chip 102, and the second side 102b may, for example, be a back side (or bottom side) of the semiconductor chip 102.

The semiconductor chip 102 may be of different types and may include, for example, integrated electrical or electro-optical circuits. The semiconductor chip 102 may, for example, include or be configured as a power semiconductor chip, for example as a power transistor such as, for example, a power MOSFET (metal-oxide-semiconductor field effect transistor) or a power IGBT (insulated-gate bipolar transistor), or as a power diode, or as a control circuit, microprocessor or microelectromechanical component, in accordance with some embodiments. In accordance with some embodiments, the semiconductor chip 102 may, for example, have a vertical structure, i.e. the semiconductor chip 102 may be configured in such a way that electric currents can flow in a direction perpendicular to the main surfaces or sides (i.e. the first side 102a and the second side 102b) of the semiconductor chip 102. A semiconductor chip 102 having a vertical structure may, for example, have contact elements on its two main sides, i.e. on the first side 102a (e.g. front side) and the second side 102b (e.g. back side) of the semiconductor chip 102. For example, power transistors and power diodes may have a vertical structure. By way of example, a first source/drain terminal (e.g. a source terminal) and a gate terminal of a power transistor or an anode terminal of a power diode may be located on one of the main sides (e.g. on the first (e.g. front) side 102a), while a second source/drain terminal (e.g. a drain terminal) of the power transistor or the cathode terminal of the power diode may be located on the other one of the main sides (e.g. on the second (e.g. back) side 102b).

The semiconductor chip 102 may include or may be made of any suitable semiconductor material or compound semiconductor material such as, for example, silicon, germanium, silicon-germanium, a ternary semiconductor material or a quaternary semiconductor material. Furthermore, in accordance with some embodiments, it may be possible that the semiconductor chip 102 includes inorganic and/or organic materials that are not semiconductors, such as, for example, insulators, plastics or metals.

In accordance with some embodiments, the semiconductor chip 102 may, for example, have one or more contact elements that may allow electrical contact to be made with the semiconductor chip 102. The contact element(s) may, for example, include or be made of any desired electrically conductive material, for example of a metal, such aluminum, gold or copper, a metal alloy or an electrically conductive organic material.

In accordance with some embodiments, the semiconductor chip 102 may, for example, have at least one contact element located on the first side 102a and/or at least one contact element located on the second side 102b.

The semiconductor device 220 may include a layer stack 103 including a plurality of electrically insulating layers 103′, 103″, as shown. The layer stack 103 may also be referred to as an insulation layer stack or multi-insulation-layer stack herein.

In accordance with the embodiment shown, the layer stack 103 may be disposed over the first side 101a of the carrier 101 between the carrier 101 and the semiconductor chip 102.

Due to the electrically insulating character of the electrically insulating layers 103′, 103″ of the layer stack 103, possible short circuits between the semiconductor chip 102 and further elements (not shown) may be avoided in accordance with some embodiments.

In accordance with the embodiment shown, the layer stack 103 may include a first electrically insulating layer 103′ and a second electrically insulating layer 103″ disposed over the first electrically insulating layer 103′.

In accordance with the embodiment shown, the first electrically insulating layer 103′ may be disposed on the first side 101a of the carrier 101. In accordance with the embodiment shown, the first electrically insulating layer 103′ of the layer stack 103 may be disposed between the carrier 101 and the second electrically insulating layer 103″ of the layer stack 103.

The first electrically insulating layer 103′ may include or may be a laminate having a first electrically insulating matrix material and a first mechanically stabilizing material embedded in the first electrically insulating matrix material. The first mechanically stabilizing material may also be referred to as first reinforcement material.

The first electrically insulating matrix material and the first mechanically stabilizing material may be different materials.

In accordance with an embodiment, the second electrically insulating layer 103″ may include or may be made of an organic insulating material, for example an organic polymer material (plastic material) such as e.g. a duroplast material, an imide material, or a resin material (e.g. epoxy resin)).

In accordance with another embodiment, the second electrically insulating layer 103″ may include or may be made of an oxide material, for example a metal oxide (e.g. aluminum oxide (alumina) or copper oxide) or a semiconductor oxide (e.g. silicon oxide), or a nitride material, for example a metal nitride (e.g. aluminum nitride) or a semiconductor nitride (e.g. silicon nitride).

In accordance with another embodiment, the second electrically insulating layer 103″ may include or may be made of a low-k material.

In accordance with another embodiment, the second electrically insulating layer 103″ may include or may be made of diamond.

In accordance with another embodiment, the second electrically insulating layer 103″ may include or may be a laminate having a second electrically insulating matrix material and a second mechanically stabilizing material embedded in the second electrically insulating matrix material. The second mechanically stabilizing material may also be referred to as second reinforcement material.

The second electrically insulating matrix material and the second mechanically stabilizing material may be different materials.

In accordance with an embodiment, the layer stack 103 may further be disposed over at least parts of the second side 101b of the carrier 101 (not shown).

In accordance with an embodiment, the layer stack 103 may further be disposed over at least parts of one or more sidewalls of the carrier 101 (not shown). For example, the layer stack 103 may be disposed over the first sidewall 101c of the carrier 101 and/or over the second sidewall 101d of the carrier 101 opposite the first sidewall 101c and/or over one or more additional sidewalls of the carrier 101 (not shown).

In accordance with an embodiment, the first electrically insulating matrix material (of the laminate of the first electrically insulating layer 103′ of the layer stack 103) may include or may be a polymer material, for example an organic polymer material (plastic material), e.g. a resin material such as, for example, epoxy resin. Alternatively or additionally, other suitable electrically insulating materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, or carbon (e.g. diamond) may be used as matrix material in the laminate.

In accordance with an embodiment, the second electrically insulating matrix material (of the laminate of the second electrically insulating layer 103″ of the layer stack 103) may include or may be a polymer material, for example an organic polymer material (plastic material), e.g. a resin material such as, for example, epoxy resin. Alternatively or additionally, other suitable electrically insulating materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, or carbon (e.g. diamond) may be used as matrix material in the laminate.

In accordance with an embodiment, the first electrically insulating matrix material and the second electrically insulating matrix material may include or may be the same material. Alternatively, the first electrically insulating matrix material and the second electrically insulating matrix material may include or may be different materials.

In accordance with an embodiment, the first mechanically stabilizing material (of the laminate of the first electrically insulating layer 103′ of the layer stack 103) may include or may be a fiber material, for example a glass fiber material. Alternatively or additionally, other suitable materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles) may be used as mechanically stabilizing material in the laminate. The first mechanically stabilizing material may be an electrically non-conductive material in accordance with some embodiments, or an electrically conductive material in accordance with other embodiments. Electrically conductive materials may generally also be good oder very good heat conductors. Use of an electrically conductive material as first mechanically stabilizing material may thus increase thermal conductivity of the first electrically insulating layer 103′.

In accordance with an embodiment, the laminate of the first electrically insulating layer 103′ may be a fiber reinforced laminate, for example a fiber reinforced plastic laminate in accordance with an embodiment, e.g. a glass fiber reinforced plastic laminate in accordance with an embodiment, for example a glass fiber reinforced epoxy resin laminate in accordance with an embodiment.

In accordance with an embodiment, the second mechanically stabilizing material (of the laminate of the second electrically insulating layer 103″ of the layer stack 103) may include or may be a fiber material, for example a glass fiber material. Alternatively or additionally, other suitable materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles) may be used as mechanically stabilizing material in the laminate. The second mechanically stabilizing material may be an electrically non-conductive material in accordance with some embodiments, or an electrically conductive material in accordance with other embodiments. Electrically conductive materials may generally also be good oder very good heat conductors. Use of an electrically conductive material as second mechanically stabilizing material may thus increase thermal conductivity of the second electrically insulating layer 103″.

In accordance with an embodiment, the first mechanically stabilizing material and the second mechanically stabilizing material may include or may be the same material. Alternatively, the first mechanically stabilizing material and the second mechanically stabilizing material may include or may be different materials.

In accordance with an embodiment, the laminate of the second electrically insulating layer 103″ may be a fiber reinforced laminate, for example a fiber reinforced plastic laminate in accordance with an embodiment, e.g. a glass fiber reinforced plastic laminate in accordance with an embodiment, for example a glass fiber reinforced epoxy resin laminate in accordance with an embodiment.

In accordance with an embodiment, the first electrically insulating layer 103′ of the layer stack 103 may have a layer thickness in the range from about 1 μm to about 1000 μm, for example in the range from about 5 μm to about 500 μm in accordance with an embodiment, for example in the range from about 10 μm to about 100 μm in accordance with an embodiment, for example a layer thickness of about 50 μm in accordance with an embodiment. In accordance with other embodiments, the layer thickness may have a different value.

In accordance with an embodiment, the second electrically insulating layer 103″ of the layer stack 103 may have a layer thickness in the range from about 1 μm to about 1000 μm, for example in the range from about 5 μm to about 500 μm in accordance with an embodiment, for example in the range from about to 10 μm about 100 μm in accordance with an embodiment, for example a layer thickness of about 50 μm in accordance with an embodiment. In accordance with other embodiments, the layer thickness may have a different value.

In accordance with an embodiment, the layer stack 103 may include one or more additional electrically insulating layers (not shown), for example a third electrically insulating layer disposed over the second electrically insulating layer 103″ in accordance with an embodiment, a fourth electrically insulating layer disposed over the third electrically insulating layer in accordance with an embodiment, a fifth electrically insulating layer disposed over the fourth electrically insulating layer in accordance with an embodiment, . . . , etc.

In general, the layer stack 103 may have any number of electrically insulating layers equal to or greater than two. For example, in accordance with an embodiment, the number of electrically insulating layers in the layer stack 103 may be in the range from two to ten, for example in the range from two to five in accordance with an embodiment. In accordance with other embodiments, the number of electrically insulating layers may be different.

The additional electrically insulating layer(s) may be configured in a similar manner as the first electrically insulating layer 103′ and/or the second electrically insulating layer 103″.

For example, in accordance with an embodiment one or more of the additional electrically insulating layer(s) may include or may be made of an organic insulating material, for example an organic polymer material (plastic material) such as e.g. a duroplast material, an imide material, or a resin material (e.g. epoxy resin)).

In accordance with another embodiment, one or more of the additional electrically insulating layer(s) may include or may be made of an oxide material, for example a metal oxide (e.g. aluminum oxide (alumina) or copper oxide) or a semiconductor oxide (e.g. silicon oxide), or a nitride material, for example a metal nitride (e.g. aluminum nitride) or a semiconductor nitride (e.g. silicon nitride).

In accordance with still another embodiment, one or more of the additional electrically insulating layer(s) may include or may be made of a low-k material.

In accordance with still another embodiment, one or more of the additional electrically insulating layer(s) may include or may be made of diamond.

In accordance with still another embodiment, one or more of the additional electrically insulating layer(s) may include or be a laminate having an electrically insulating matrix material and a mechanically stabilizing material embedded in the electrically insulating matrix material.

The (respective) electrically insulating matrix material(s) of the additional electrically insulating layer(s) and the (respective) mechanically stabilizing material(s) of the additional electrically insulating layer(s) may be different materials.

In accordance with an embodiment, the (respective) electrically insulating matrix material(s) (of the laminate(s) of the additional electrically insulating layer(s) of the layer stack) may include or may be a polymer material, for example an organic polymer material (plastic material), e.g. a resin material such as, for example, epoxy resin. Alternatively or additionally, other suitable electrically insulating materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, or carbon (e.g. diamond) may be used as matrix material(s) in the laminate(s).

In accordance with an embodiment, the electrically insulating matrix material(s) of the laminate(s) of one or more of the additional electrically insulating layers may be the same as the first electrically insulating matrix material (of the laminate of the first electrically insulating layer 103′ of the layer stack 103) and/oder as the second electrically insulating matrix material (of the laminate of the second electrically insulating layer 103″ of the layer stack 103).

In accordance with an embodiment, the electrically insulating matrix material in each additional electrically insulating layer may be the same. Alternatively, the electrically insulating matrix materials of the additional electrically insulating layers may be different.

In accordance with an embodiment, the (respective) mechanically stabilizing material(s) (of the laminate(s) of the additional electrically insulating layer(s) of the layer stack 103) may include or may be a fiber material, for example a glass fiber material. Alternatively or additionally, other suitable materials such as, for example oxides (e.g. a semiconductor oxide such as silicon oxide, or a metal oxide (e.g. alumina)), nitrides (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles) may be used as mechanically stabilizing material(s) in the laminate(s). The (respective) mechanically stabilizing material(s) may be an electrically non-conductive material in accordance with some embodiments, or an electrically conductive material in accordance with other embodiments. Electrically conductive materials may generally also be good oder very good heat conductors. Use of an electrically conductive material as mechanically stabilizing material may thus increase thermal conductivity of the additional electrically insulating layer(s).

In accordance with an embodiment, the mechanically stabilizing material in each additional electrically insulating layer may be the same. Alternatively, the mechanically stabilizing materials of the additional electrically insulating layers may be different.

In accordance with an embodiment, the laminate of each additional electrically insulating layer may be a fiber reinforced laminate, for example a fiber reinforced plastic laminate in accordance with an embodiment, e.g. a glass fiber reinforced plastic laminate in accordance with an embodiment, for example a glass fiber reinforced epoxy resin laminate in accordance with an embodiment.

In accordance with an embodiment, at least one of the additional electrically insulating layers of the layer stack 103 may have a layer thickness in the range from about 1 μm to about 1000 μm, for example in the range from about 5 μm to about 500 μg in accordance with an embodiment, for example in the range from about 10 μm to about 100 μm in accordance with an embodiment, for example a layer thickness of about 50 μm in accordance with an embodiment. In accordance with other embodiments, the layer thickness may have a different value.

In accordance with an embodiment, the layer stack may 103 have a total layer thickness in the range from about 2 μm to about 10000 μm, for example in the range from about 10 μm to about 5000 μm in accordance with an embodiment, for example in the range from about 20 μm to about 1000 μm in accordance with an embodiment, for example in the range from about 100 μm to about 500 μm in accordance with an embodiment. Alternatively, the total layer thickness may have a different value. In accordance with an embodiment, the total layer thickness may be the sum of the layer thicknesses of the individual electrically insulating layers (i.e. the first electrically insulating layer 103′, the second electrically insulating layer 103″ and possibly additional electrically insulating layers) of the layer stack 103.

In accordance with an embodiment, an electrically conductive layer 204 may be disposed between the layer stack 103 and the semiconductor chip 102.

In accordance with an embodiment, the second side 102b (e.g. back side) of the semiconductor chip 102 may face the electrically conductive layer 204.

In accordance with an embodiment, the semiconductor chip 102 may be electrically coupled to the electrically conductive layer 204, for example by means of an electrical contact element disposed on the second side 102b of the semiconductor chip 102 (e.g. by means of a back side metallization of the semiconductor chip 102 in accordance with an embodiment) (not shown). Thus, the electrically conductive layer 204 may serve to electrically contact the semiconductor chip 102.

In accordance with an embodiment, the semiconductor device 220 may further include an encapsulation structure (not shown, see e.g. FIG. 3A) that may, for example, serve to protect the semiconductor chip 102 against external influences such as, for example, dirt, humidity or mechanical impact.

In accordance with an embodiment, at least one of the carrier 101, the semiconductor chip 102 and the layer stack 103 may be at least partly covered by the encapsulation structure. In other words, the carrier 101 and/or the semiconductor chip 102 and/or the layer stack 103 may be at least partly covered by the encapsulation structure in accordance with an embodiment.

In accordance with an embodiment, the encapsulation structure may include or may be made of an encapsulation material, for example a mold compound in accordance with an embodiment. The implementation of the mold compound may be arbitrary. In accordance with an embodiment, the mold compound may, for example, include or may be made of a polymer material such as, for example, a resin (e.g. epoxy resin) or silicone. In accordance with other embodiments, the mold compound may include or may be made of other suitable materials, e.g. other suitable moldable materials. The mold compound may not be restricted to be made of a specific material and combinations of different materials may be possible as well. In accordance with other embodiments, the encapsulation material may include or may be another suitable material.

In accordance with an embodiment, the semiconductor device 220 may further include a heat sink (not shown). The heat sink may be coupled to at least one of the carrier 101 and the layer stack 103. For example, in accordance with an embodiment, the heat sink may be coupled to the second side 101b of the carrier 101.

In accordance with an embodiment, the heat sink may include or may be made of a material with a high thermal conductivity, for example a metal or a metal alloy in accordance with an embodiment, alternatively other suitable materials with a high thermal conductivity.

In accordance with some embodiments, the semiconductor device 220 may also be referred to as a module.

During fabrication of the semiconductor device 220, the layer stack 103 may be formed over the first side 101a of the carrier 101. The layer stack 103 may be formed before mounting the semiconductor chip 102.

The layer stack 103 may be formed by subsequently forming the individual electrically insulating layers (i.e. the first electrically insulating layer 103′ and the second electrically insulating layer 103″, and possibly additional electrically insulating layers (not shown) in accordance with some embodiments) one over the other.

Each of the electrically insulating layers of the layer stack 103, more precisely the laminate of each of the electrically insulating layers, may be formed by means of any suitable lamination process, e.g. any suitable process to form a reinforced (e.g. fiber reinforced) laminate material, such as, for example, laminating, varnishing, or molding (e.g. injection molding).

The electrically insulating layers of the layer stack 103 may be formed in separate process steps that may, for example, be separated in time. For example, a certain time period may elapse between the formation of two consecutive layers of the stack 103 in accordance with an embodiment. Thus, even in case that two adjacent electrically insulating layers of the layer stack 103 are made of the same materials, it may be possible to distinguish the two layers from one another in accordance with various embodiments. For example, a distinct interface may be seen at the location where the surfaces of the two layers meet in accordance with various embodiments. At the interface, each of the two adjacent layers may have surface properties instead of bulk properties. For example, at the interface each of the two adjacent layers may exhibit a molecular or atomic arrangement that is characteristic for its surface, instead of a molecular or atomic arrangement that is characteristic for its bulk. Illustratively, by forming a plurality of distinct electrically insulating layers (instead of a single contiguous layer), an electrical insulation having one or more predetermined “breaking points” (i.e. interfaces where the bulk structure may clearly be interrupted) may be generated, as will, for example, be described in further detail herein below in connection with FIG. 8A.

FIG. 2C shows a schematic sectional side view of a semiconductor device 240 in accordance with another embodiment.

The semiconductor device 240 is to some extent similar to the semiconductor device 220 shown in FIG. 2B. In particular, the same reference numerals denote the same elements as there and will not be described again here in detail for sake of brevity.

The semiconductor device 240 is different from the semiconductor device 220 in that the second electrically insulating layer 103″ of the layer stack 103 in the semiconductor device 240 is disposed between the carrier 101 and the first electrically insulating layer 103′ of the layer stack 103. In other words, the sequence of the electrically insulating layers 103′, 103″ is reversed compared to that in FIG. 2B.

As will be readily understood, the layer stack 103 of the semiconductor device 240 may include additional (e.g. electrically insulating) layers, which may, for example, be configured in a similar or the same manner as the first and/or second electrically insulating layer 103′, 103″.

FIG. 3A shows a schematic sectional side view of a semiconductor device 300 in accordance with another embodiment.

The semiconductor device 300 is to some degree similar to the semiconductor device 120 shown and described in connection with FIG. 1B. In particular, the same reference signs denote the same elements as in FIG. 1B and will not be described in detail again here for sake of brevity. Reference is made to the description herein above.

In accordance with the embodiment shown, the layer stack 103 of the semiconductor device 300 may include a third electrically insulating layer 103′ in addition to the first electrically insulating layer 103′ and the second electrically insulating layer 103″, as shown (in accordance with further embodiments, the layer stack 103 may include only the first electrically insulating layer 103′, or the first electrically insulating layer 103′ and one of the second and third electrically insulating layers 103″, 103′″, or may include more than three electrically insulating layers). The third electrically insulating layer 103′″ may be configured in a similar manner as the first electrically insulating layer 103′ and/or the second electrically insulating layer 103″ of the layer stack 103, for example with respect to material composition and/or layer thickness.

The semiconductor device 300 may include an encapsulation structure 305 that may cover the carrier 101, the semiconductor chip 102, as well as the electrically insulating layers 103′, 103″, 103′ of the layer stack 103. The encapsulation structure 305 may, for example, serve to protect the semiconductor chip 102 against external influences such as, for example, dirt, humidity or mechanical impact.

In accordance with an embodiment, the encapsulation structure 305 may include or may be made of an encapsulation material, for example a mold compound in accordance with an embodiment. The implementation of the mold compound may be arbitrary. In accordance with an embodiment, the mold compound may, for example, include or may be made of a polymer material such as, for example, a resin (e.g. epoxy resin) or silicone. In accordance with other embodiments, the mold compound may include or may be made of other suitable materials, e.g. other suitable moldable materials. In accordance with other embodiments, the encapsulation material may include or may be another suitable material.

The semiconductor device 300 may further include a heat sink 306. The heat sink 306 may be connected to the layer stack 103, for example to the outermost layer of the layer stack 103, i.e. to the third electrically insulating layer 103′″ in accordance with the embodiment shown.

The heat sink 306 may include or may be made of a material with a high thermal conductivity, for example a metal or a metal alloy in accordance with an embodiment, alternatively other suitable materials with a high thermal conductivity.

Due to the insulating behavior of the electrically insulating layers 103′, 103″, 103′″ of the layer stack 103, possible short circuits between the carrier 101 (or, respectively, the semiconductor chip 102) and the heat sink 306 may be avoided.

In accordance with the embodiment shown in FIG. 3A, the carrier 101, the semiconductor chip 102 and the layer stack 103 may be completely covered by the encapsulation structure (e.g. mold compound) 305. In accordance with other embodiments, it may be possible that the encapsulation structure 305 covers only single elements or arbitrary combinations of elements of the semiconductor device 300. It may also be possible that the covering by the encapsulation structure 305 is only a partial covering, i.e. one or more elements of the semiconductor device 300 may not need to be completely covered by the encapsulation structure 305.

The third electrically insulating layer 103′″ (or, in general, at least one of the electrically insulating layers of the layer stack 103) may be arranged between the heat sink 306 and the encapsulation structure (e.g. mold compound) 305, as shown. This may, for example, have the effect that negative electric or magnetic effects that might occur in case of the heat sink 306 directly contacting the encapsulation structure 305 may be avoided. In accordance with other embodiments, it may be possible that the encapsulation structure 305 directly contacts the heat sink 306.

In accordance with some embodiments, one or more electrical connection elements may be provided in the semiconductor device 300 that may provide an electrical connection between the semiconductor device 300 and possible exterior contacts or applications. In the case of a semiconductor device including elements completely covered by the encapsulation structure 305, such an electrical connection may, for example, be realized by means of a lead frame with its pins providing the desired electrical connection, in accordance with an embodiment. An electrical connection between one or more electrical contacts of the semiconductor device 300 and the lead frame may, for example, be realized by one or more bonding wires, in accordance with an embodiment.

In accordance with other embodiments, the layer sequence in the layer stack 103 of the semiconductor device 300 may be different from the one shown in FIG. 3A. For example, in accordance with one embodiment, the first electrically insulating layer 103′ may be disposed between the second electrically insulating layer 103″ and the third electrically insulating layer 103′″, as is shown in FIG. 3B, or in accordance with another embodiment the first and third electrically insulating layers 103′, 103′″ may swap positions, as is shown in FIG. 3C.

FIG. 3B shows a semiconductor device 320 in accordance with another embodiment. The semiconductor device 320 is to some extent similar to the semiconductor device 300 shown in FIG. 3A. In particular, the same reference numerals denote the same elements as there and will not be described again here in detail for sake of brevity.

The semiconductor device 320 is different from the semiconductor device 300 in that the first electrically insulating layer 103′ is disposed between the second electrically insulating layer 103″ and the third electrically insulating layer 103′.

FIG. 3C shows a semiconductor device 340 in accordance with another embodiment. The semiconductor device 340 is to some extent similar to the semiconductor device 300 shown in FIG. 3A. In particular, the same reference numerals denote the same elements as there and will not be described again here in detail for sake of brevity.

The semiconductor device 340 is different from the semiconductor device 300 in that the first and third electrically insulating layers 103′, 103′″ have swapped positions compared to the arrangement in FIG. 1A. That is, the first electrically insulating layer 103′ may be formed between the second electrically insulating layer 103″ and the heat sink 306, and the second electrically insulating layer 103″ may be formed between the first electrically insulating layer 103′ and the third electrically insulating layer 103′″, as shown.

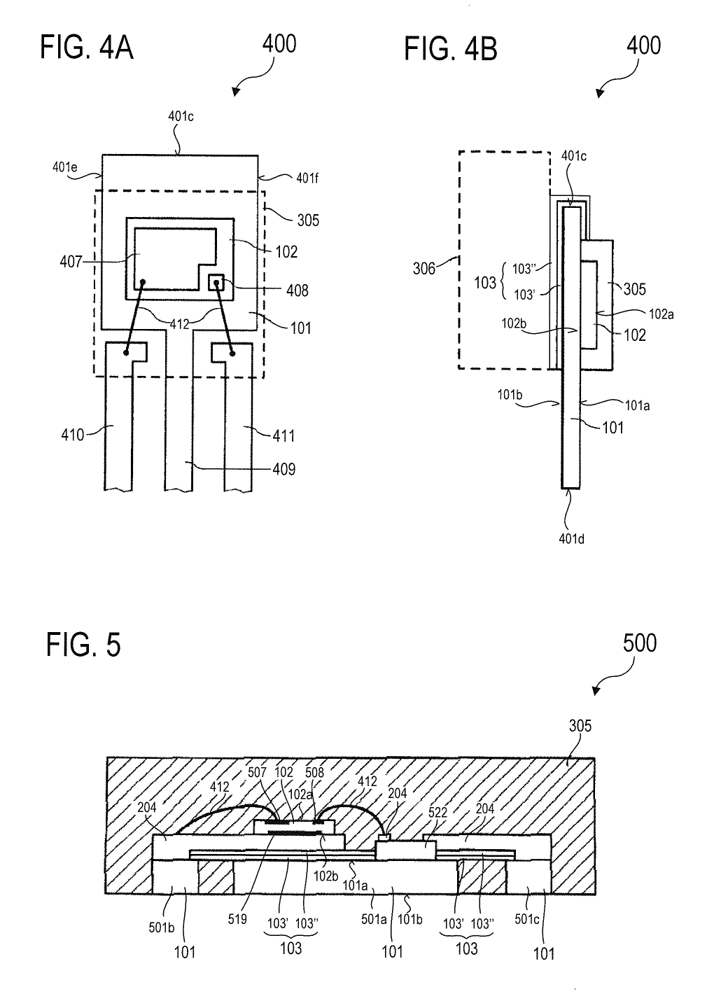

FIG. 4A and FIG. 4B show, as a schematic plan view (FIG. 4A) and as a schematic sectional side view (FIG. 4B), a semiconductor device 400 in accordance with another embodiment.

The semiconductor device 400 may include a carrier (or carrier element) 101 and a semiconductor chip 102 mounted on the carrier 101.

The carrier 101 may have a first side 101a and a second side 101b, as shown. As shown, the first side 101a and the second side 101b of the carrier 101 may be opposite sides of the carrier 101. The first side 101a of the carrier 101 may be a top side of the carrier 101 and the second side 101b of the carrier 101 may be a bottom side of the carrier 101. The carrier 101 may further have a first sidewall 101c, a second sidewall 101d opposite the first sidewall 101c, a third sidewall 101e, and a fourth sidewall 101f opposite the third sidewall 101e, as shown.

The carrier 101 may include or be made of an electrically conductive material such as, for example, a metal or a metal alloy, for example copper or a copper alloy, aluminum or an aluminum alloy, or other suitable metals or metal alloys.

The semiconductor chip 102 may be disposed over the first side 101a of the carrier 101.

The semiconductor chip 102 may have a first side 102a and a second side 102b opposite the first side 102a, as shown. The first side 102a may be a front side or top side of the semiconductor chip 102, and the second side 102b may be a back side or bottom side of the semiconductor chip 102.

The semiconductor chip 102 may be configured as a transistor chip or transistor, for example as a power transistor, e.g. as a power MOSFET in accordance with an embodiment. Thus, the semiconductor device 400 may also be referred to as a transistor module, for example as a power transistor module in case the semiconductor chip 102 is configured as a power transistor.

In accordance with an embodiment, the first side (top side) 102a of the semiconductor chip 102 may, for example, provide a source terminal 407 and a gate terminal 408 of the transistor while the second side (bottom side) 102b of the semiconductor chip 102 may represent a drain terminal of the transistor.

The semiconductor chip 102 may be mounted with its second side (bottom side) 102b, i.e. with the drain terminal of the transistor, to the carrier 101, which in this embodiment is configured to have a first terminal leg 409.

The semiconductor chip 102 may be covered by an encapsulation structure 305 (e.g. a mold compound), indicated by a dashed line in FIG. 4A, with the first terminal leg 409 of the carrier 101 and a second terminal leg 410 and a third terminal leg 411 projecting out of the encapsulation structure 305. The terminal legs 409, 410, 411 may provide an electrical connection to possible exterior applications. The first terminal leg 409 may constitute a drain terminal of the semiconductor device 400, while the second and third terminal legs 410, 411 may be respectively connected to the source terminal 407 and the gate terminal 408 of the semiconductor chip (transistor) 102 via respective bond wires 412.

As shown, a layer stack 103 including a plurality of electrically insulating layers 103′, 103″ may be disposed over a part of the second side (bottom side) 101b, over the first sidewall 101c and over a part of the first side (top side) 101a of the carrier 101 (not shown in FIG. 4A but shown in FIG. 4B). In accordance with an embodiment, the layer stack 103 may, for example, further be disposed over the third sidewall 101e and/or over the fourth sidewall 101f of the carrier 101 (not shown).

As an example, the layer stack 103 includes a first electrically insulating layer 103′ and a second electrically insulating layer 103″ disposed over the first electrically insulating layer 103′, however, more than two electrically insulating layers may be provided in accordance with other embodiments.

Due to the electrically insulating character of the electrically insulating layers 103′, 103″ of the layer stack 103, possible short circuits between the carrier 101 (respectively the semiconductor chip 102) and further elements (not shown) may be avoided in accordance with some embodiments.

The electrically insulating layers 103′, 103″ may, for example, be configured in a similar manner (e.g. with respect to material composition) as described herein above. For example, in accordance with one embodiment, each of the electrically insulating layers 103′, 103″ may include or may be a laminate having an electrically insulating matrix material and a mechanically stabilizing material embedded in the electrically insulating matrix material. The mechanically stabilizing material may also be referred to as reinforcement material. In accordance with another embodiment, it may be possible that only the first electrically insulating layer 103′ is configured as a laminate.

The electrically insulating layers 103′, 103″ of the layer stack may, for example, be configured in the same or a similar manner as described herein above in connection with the embodiments shown in the preceding figures.

A heat sink 306 may be connected to the layer stack 103, as shown in FIG. 4B. The heat sink 306 may, for example, be configured in the same or a similar manner as described herein above in connection with the embodiments shown in the preceding figures.

The layer stack 103 may be formed by subsequently forming the individual electrically insulating layers (i.e. the first electrically insulating layer 103′ and the second electrically insulating layer 103″, and possibly additional electrically insulating layers (not shown) in accordance with some embodiments) one over the other.

Each electrically insulating layer of the layer stack 103 including or being a laminate, more precisely the laminate of the electrically insulating layer, may be formed by means of any suitable lamination process, e.g. any suitable process to form a reinforced (e.g. fiber reinforced) laminate material, such as, for example, laminating, varnishing, or molding (e.g. injection molding).

The electrically insulating layers of the layer stack 103 may be formed in separate process steps that may, for example, be separated in time. For example, a certain time period may elapse between the formation of two consecutive layers of the stack 103 in accordance with an embodiment. Thus, even in case that two adjacent electrically insulating layers of the layer stack 103 are made of the same materials, it may be possible to distinguish the two layers from one another in accordance with various embodiments. For example, a distinct interface may be seen at the location where the surfaces of the two layers meet in accordance with various embodiments. At the interface, each of the two adjacent layers may have surface properties instead of bulk properties. For example, at the interface each of the two adjacent layers may exhibit a molecular or atomic arrangement that is characteristic for its surface, instead of a molecular or atomic arrangement that is characteristic for its bulk. Illustratively, by forming a plurality of distinct electrically insulating layers (instead of a single contiguous layer), an electrical insulation having one or more predetermined “breaking points” (i.e. interfaces where the bulk structure may clearly be interrupted) may be generated, as will, for example, be described in further detail herein below in connection with FIG. 8A.

In accordance with another embodiment, the layer stack 103 of the semiconductor device 400 may include only the first electrically insulating layer 103′. In accordance with another embodiment, the layer sequence in the layer stack 103 may be reversed. In other words, the second electrically insulating layer 103″ may be disposed between the first electrically insulating layer 103′ and the carrier 101 in accordance with an embodiment.

FIG. 5 shows a schematic sectional side view of a semiconductor device 500 in accordance with another embodiment. The same reference numerals denote the same elements as described herein above in connection with the embodiments shown in the previous figures and will not be described again here in detail for sake of brevity. Reference is made to the description above.

The semiconductor device 500 may include a carrier 101. The carrier 101 may be configured as a lead frame including a die pad 501a and pins 501b, 501c (only a first pin 501b and a second pin 501c are shown in the cross-sectional view, however the carrier 101 may have additional pins that may, for example, be hidden behind the pins 501b, 501c and not shown in FIG. 5).

The carrier 101 (i.e. lead frame) may be electrically conductive and may, for example, be made of a metal or metal alloy in accordance with an embodiment. Alternatively, the carrier 101 may include or may be made of other electrically conductive materials.

The semiconductor device 500 may include a semiconductor chip 102 disposed over a first side 101a of the carrier. The semiconductor chip 102 may be disposed over the die pad 501a of the carrier 101, as shown. The semiconductor chip 102 may, for example, be configured as a power transistor, e.g. as a power MOSFET in accordance with an embodiment. The semiconductor chip 102 may include a first contact element 507 (for example a source terminal of the power transistor) and a second contact element 508 (for example a gate terminal of the power transistor) located on a front side 102a the semiconductor chip 102 and a third contact element 519 (for example a drain terminal of the power transistor) located on a back side 102b of the semiconductor chip 102. The back side 102b of the semiconductor chip 102 may face the carrier 101, as shown.

A layer stack 103 including a plurality of electrically insulating layers 103′, 103″ may be disposed between the carrier 101 and the semiconductor chip 102. A first electrically insulating layer 103′ and a second electrically insulating layer 103″ are shown as an example, however, the layer stack 103 may include additional electrically insulating layers in accordance with other embodiments. The electrically insulating layer 103′, 103″ may, for example, be configured in accordance with one or more embodiments described herein.

An electrically conductive layer 204 may be disposed between the layer stack 103 and the semiconductor chip 102. The electrically conductive layer 204 may contact the third contact element 519 of the semiconductor chip 102 (e.g. drain terminal of the power transistor) on the back side 102b of the semiconductor chip 102 and the first pin 501b (e.g. a drain pin) of the carrier 101. The die pad 501a of the carrier 101 may be electrically insulated from the electrically conductive layer 204 and thus from the third contact element 519 of the semiconductor chip 102 (e.g. drain terminal of the power transistor) by means of the electrically insulating layers 103′, 103″ of the layer stack 103.

The first electrical contact element 507 of the semiconductor chip 102 (e.g. source terminal of the power transistor) may be electrically connected to one or more pins of the carrier 101 by means of one or more bond wires 412. The pin or pins are not shown in the cross-sectional view of FIG. 5 but may, for example, lie behind the second pin 501b.

The semiconductor device 500 may include an additional semiconductor chip 522. The additional semiconductor chip 522 may be disposed over the first side 101a of the carrier 101. The additional semiconductor chip 522 may, for example, be disposed over the die pad 501a of the carrier 101, as shown. In accordance with the embodiment shown, the additional semiconductor chip 522 may directly contact the die pad 501a, although in accordance with other embodiments, one or more layers or elements may be disposed between the additional semiconductor chip 522 and the die pad 501a. The additional semiconductor chip 522 may, for example, be configured as a control chip and may, for example, be electrically coupled to the second electrical contact 508 of the semiconductor chip 102 (e.g. gate terminal of the power transistor) via a bond wire 412, as shown. For example, the additional semiconductor chip 522 may provide a control potential (e.g. gate control potential) at the second electrical contact 508 (gate terminal) of the semiconductor chip (e.g. power transistor) 102.

The additional semiconductor chip 522 may further be electrically coupled to the second pin 501c of the carrier 101 (and possibly to additional pins not shown) by means of the electrically conductive layer 204.

The layer stack 103 may electrically insulate the semiconductor chip 102 (in particular, the third electrical contact element 519 (e.g. drain terminal) of the semiconductor chip 102) from the die pad 501a and thus from the additional semiconductor chip 522. For example, in case that the semiconductor chip 102 is configured as a power MOSFET, the drain voltage (voltage at the drain terminal 519) may, for example, be up to about 1 kV or even more. Since the die pad 501a may be electrically insulated from the power MOSFET 102, the additional semiconductor chip 522 (e.g. control chip) may contact the die pad 501a without experiencing any damage caused by the high voltages of the power MOSFET 102.

Components of the semiconductor device 500 may be covered with an encapsulation structure 305, as shown. The encapsulation structure 305 may, for example, include or be made of a mold compound, alternatively any other suitable encapsulation material. The encapsulation structure 305 may, for example, serve to protect components of the semiconductor device 500 against external (e.g. environmental) influences such as, for example, dirt, humidity or mechanical impact. In accordance with the embodiment shown, the bottom side 101b of the carrier 101 is free from the encapsulation structure 500. In other words, the bottom side of the lead frame, more precisely the bottom sides of the die pad 501a and of the pins 501b, 501c (and of additional pins not shown in FIG. 5), may be exposed. Thus, for example one or more of the pins may be electrically connected to/from the outside.

In accordance with an embodiment, a heat sink (not shown in FIG. 5, see e.g. FIG. 3A or FIG. 4B) may be thermally coupled to the die pad 501a. During operation, heat generated by the semiconductor chip 102 (e.g. power transistor) and/or the additional semiconductor chip 522 (e.g. control chip) may be dissipated from the semiconductor device 500 by the heat sink. An effective dissipation path may proceed from the bottom surfaces of the semiconductor chips 102, 522 towards the heat sink, thereby crossing the layer stack 103 and the die pad 501a. In accordance with some embodiments, the thickness and/or the material of the electrically insulating layers 103′, 103″ of the layer stack 103 may, for example, be chosen in a way to provide both a high thermal conductivity and good insulating properties at the same time. In accordance with an embodiment, the bottom surface of the semiconductor device 500 may, for example, also be used to mount the device 500 onto a circuit board, for example a PCB (Printed Circuit Board). The parts of the die pad 501a and the pins 501b, 501c which are not covered with the encapsulation structure (e.g. mold compound) 305 may, for example, be connected (e.g. soldered) to one or more contact areas of the circuit board, in accordance with an embodiment.

In accordance with another embodiment, the layer stack 103 of the semiconductor device 500 may include only the first electrically insulating layer 103′. In accordance with another embodiment, the layer sequence in the layer stack 103 may be reversed. In other words, the second electrically insulating layer 103″ may be disposed between the first electrically insulating layer 103′ and the carrier 101 in accordance with an embodiment.

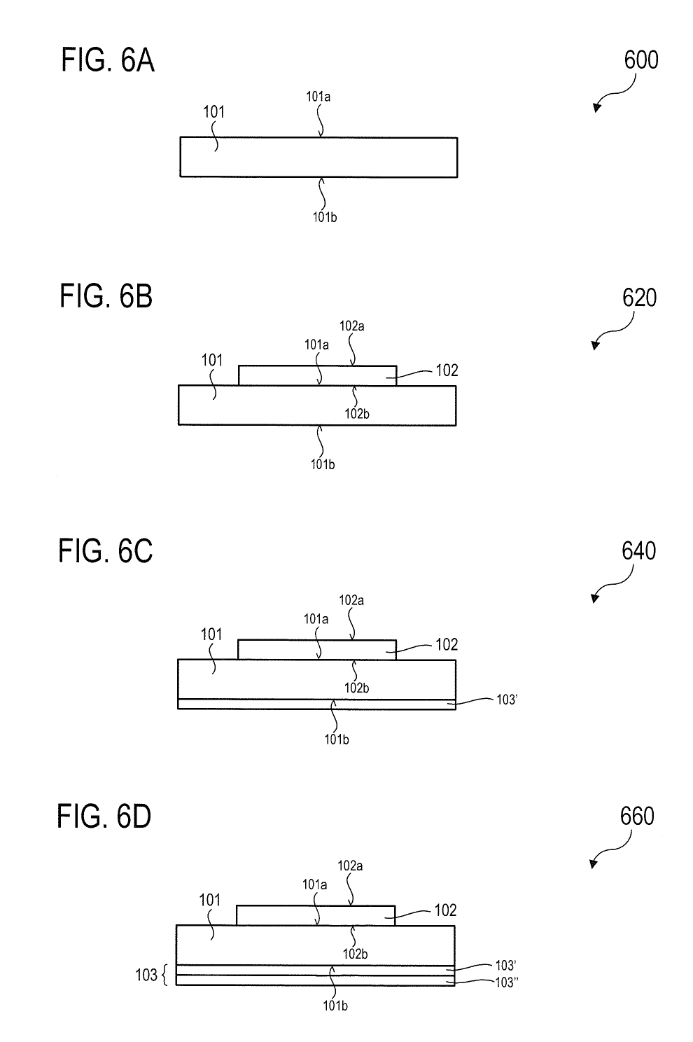

FIGS. 6A to 6C show various views illustrating a method of fabricating a semiconductor device in accordance with another embodiment, and FIG. 6D shows a view illustrating a method of fabricating a semiconductor device in accordance with still another embodiment.

FIG. 6A shows, in a schematic sectional side view 600, that a carrier 101 may be provided. The carrier 101 may have a first side 101a and a second side 101b opposite the first side 101a. The first side 101a may, for example, be a top side of the carrier 101 and the second side 101b may, for example, be a bottom side of the carrier 101. The carrier 101 may, for example, further be configured in accordance with one or more embodiments described herein.

FIG. 6B shows, in a schematic sectional side view 620, that a semiconductor chip 102 may be disposed over (for example, on) the carrier 101, for example over (e.g. on) the first side 101a of the carrier 101. The semiconductor chip 101 may have a first side 102a and a second side 102b opposite the first side 102b. The first side 102a may, for example, be a front side of the semiconductor chip 102 and the second side 102b may, for example, be a back side of the semiconductor chip 102. The semiconductor chip 102 may, for example, further be configured in accordance with one or more embodiments described herein.

FIG. 6C shows, in a schematic sectional side view 640, that a first electrically insulating layer 103′ may be disposed over (e.g. on) the second side 101b (e.g. bottom side) of the carrier 101. The first electrically insulating layer 103′ may include or may be made of a laminate including an electrically insulating matrix material and a mechanically stabilizing material embedded in the electrically insulating matrix material, for example a fiber reinforced laminate material in accordance with an embodiment. Alternatively or in addition, the first electrically insulating layer 103′ may be configured in accordance with one or more embodiments described herein.

The first electrically insulating layer 103′ may be formed using any suitable process to form a laminate.

In a method of fabricating a semiconductor device in accordance with still another embodiment, one or more additional electrically insulating layers may be formed, as shown in FIG. 6D.

FIG. 6D shows, in a schematic sectional side view 660, that a second electrically insulating layer 103″ may be disposed over (e.g. on) the first electrically insulating layer 103′.

In accordance with one embodiment, the second electrically insulating layer 103″ may include or may be made of an organic insulating material, for example an organic polymer material (plastic material) such as e.g. a duroplast material, an imide material, or a resin material (e.g. epoxy resin)). In this case, the second electrically insulating layer 103″ may, for example, be formed using any suitable process for forming an organic insulating layer.

In accordance with another embodiment, the second electrically insulating layer 103″ may include or may be made of an oxide material, for example a metal oxide (e.g. aluminum oxide (alumina) or copper oxide) or a semiconductor oxide (e.g. silicon oxide), or a nitride material, for example a metal nitride (e.g. aluminum nitride) or a semiconductor nitride (e.g. silicon nitride). In this case, the second electrically insulating layer 103″ may, for example, be formed using any suitable process (e.g. deposition process) for forming an oxide layer or nitride layer.

In accordance with another embodiment, the second electrically insulating layer 103″ may include or may be made of a low-k material.

In accordance with another embodiment, the second electrically insulating layer 103″ may include or may be made of diamond. In this case, the second electrically insulating layer 103″ may, for example, be formed using any suitable process for forming a diamond layer or diamond-containing layer.

In accordance with another embodiment, the second electrically insulating layer 103″ may include or may be made of a laminate including an electrically insulating matrix material and a mechanically stabilizing material embedded in the electrically insulating matrix material, for example a fiber reinforced laminate material in accordance with an embodiment.

In accordance with an embodiment, the laminate of the second electrically insulating layer 103″ may include or may be made of the same material(s) as the laminate of the first electrically insulating layer 103′. In accordance with another embodiment, the laminates of the first and second electrically insulating layers 103′, 103″ may include or may be made of different materials. Alternatively or in addition, the second electrically insulating layer 103′ may be configured in accordance with one or more embodiments described herein.

The second electrically insulating layer 103″ may be formed using any suitable process to form a laminate.

The first electrically insulating layer 103′ and the second electrically insulating layer 103″ thus form a layer stack 103 that includes a plurality of electrically insulating layers.

In accordance with other embodiments, the layer stack 103 may include additional electrically insulating layers. That is, one or more additional electrically insulating layers may be formed over the second electrically insulating layer 103″. The individual layers may be formed consecutively and may be configured in a similar or the same manner as the first electrically insulating layer 103′ and/or second electrically insulating layer 103″.

It should be noted that, in accordance with some embodiments, the semiconductor chip 102 may be disposed over the carrier 101 after the layer stack 103 has been formed.

In accordance with further embodiments, additional components may be formed or provided such as, for example, one or more electrical connections (e.g. bond wires) between the semiconductor chip 102 and external terminals (e.g. pins) and/or additional chips, an encapsulation structure (e.g. mold compound), a heat sink, one or more additional chips, etc. (not shown).

It should be noted that, in accordance with some embodiments, the layer stack 103 shown in FIG. 6D may additionally be formed over parts of the first side (top side) 101a and/or over at least parts of one or more sidewalls of the carrier 101 (not shown).

One effect of forming a layer stack 103 having a plurality of individual electrically insulating layers 103′, 103″ may be that an improved electrical insulation may be achieved because it may be avoided that defects such as pin holes reach through the whole insulation, as will be described in more detail further below in connection with FIG. 8A and FIG. 8B.

In accordance with another embodiment, the layer sequence in the layer stack 103 may be reversed. In other words, the second electrically insulating layer 103″ may be formed before the first electrically insulating layer 103′ so that the electrically insulating layer 103″ may be disposed between the carrier 101 and the first electrically insulating layer 103′.

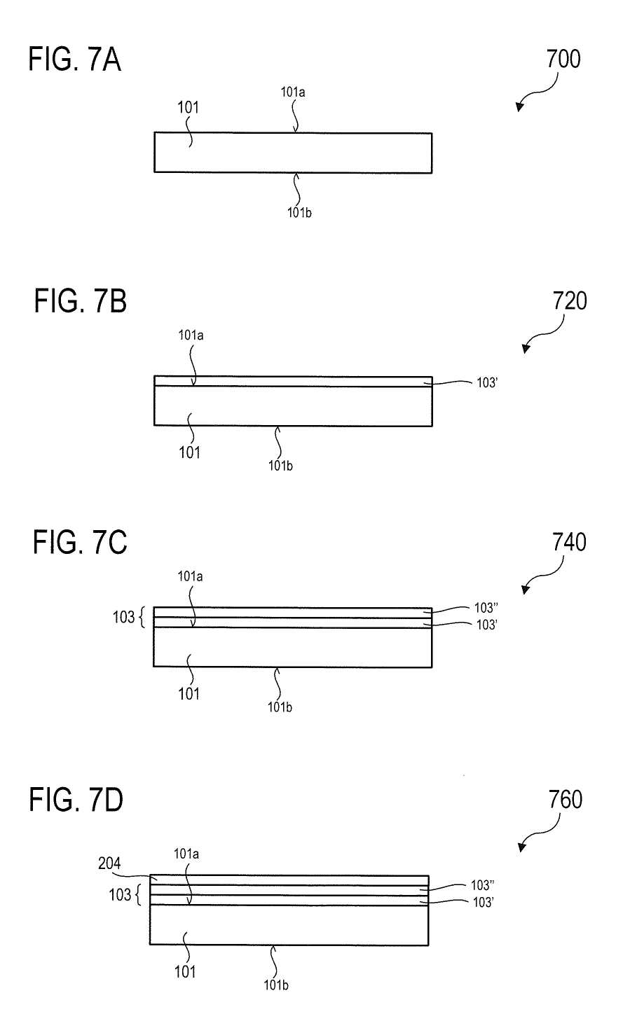

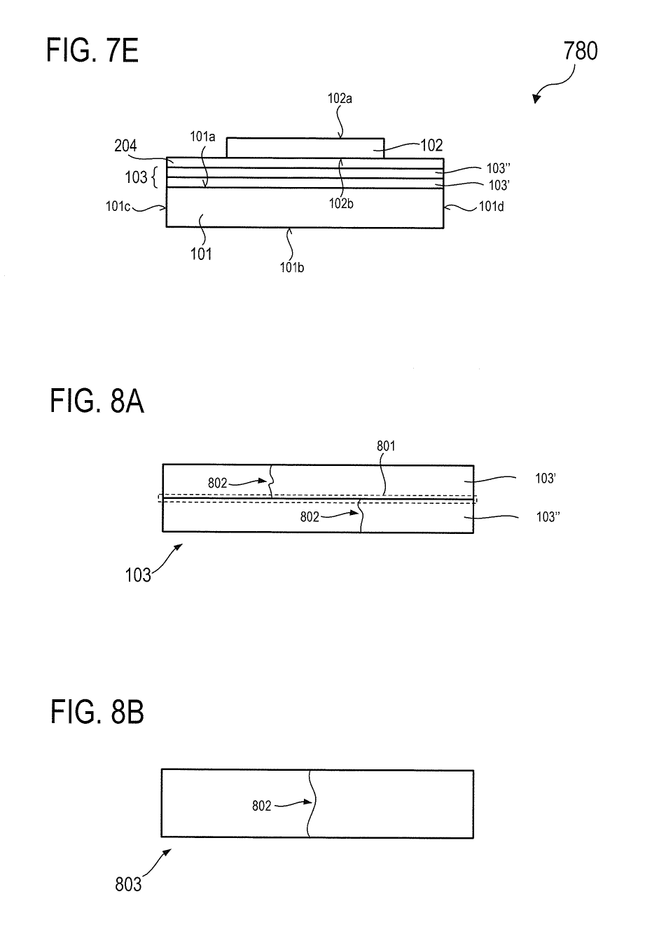

FIGS. 7A to 7E show various stages in a method of fabricating a semiconductor device in accordance with another embodiment.

FIG. 7A shows, in a schematic sectional side view 700, that a carrier 101 may be provided. The carrier 101 may have a first side 101a and a second side 101b opposite the first side 101a. The first side 101a may, for example, be a top side of the carrier 101 and the second side 101b may, for example, be a bottom side of the carrier 101. The carrier 101 may, for example, further be configured in accordance with one or more embodiments described herein.

FIG. 7B shows, in a schematic sectional side view 720, that a first electrically insulating layer 103′ may be disposed over (e.g. on) the first side 101a (e.g. top side) of the carrier 101. The first electrically insulating layer 103′ may include or may be made of a laminate including an electrically insulating matrix material and a mechanically stabilizing material embedded in the electrically insulating matrix material, for example a fiber reinforced laminate material in accordance with an embodiment. Alternatively or in addition, the first electrically insulating layer 103′ may be configured in accordance with one or more embodiments described herein.

The first electrically insulating layer 103′ may be formed using any suitable process to form a laminate.

FIG. 7C shows, in a schematic sectional side view 740, that a second electrically insulating layer 103″ may be disposed over (e.g. on) the first electrically insulating layer 103′.

In accordance with an embodiment, the second electrically insulating layer 103″ may include or may be made of an organic insulating material, for example an organic polymer material (plastic material) such as e.g. a duroplast material, an imide material, or a resin material (e.g. epoxy resin)). In this case, the second electrically insulating layer 103″ may be formed using any suitable process for forming an organic insulating layer.

In accordance with another embodiment, the second electrically insulating layer 103″ may include or may be made of an oxide material, for example a metal oxide (e.g. aluminum oxide (alumina) or copper oxide) or a semiconductor oxide (e.g. silicon oxide), or a nitride material, for example a metal nitride (e.g. aluminum nitride) or a semiconductor nitride (e.g. silicon nitride). In this case, the second electrically insulating layer 103″ may be formed using any suitable process for forming an oxide layer or oxide-containing layer, or a nitride layer or nitride-containing layer.

In accordance with another embodiment, the second electrically insulating layer 103″ may include or may be made of a low-k material. In this case, the second electrically insulating layer 103″ may be formed using any suitable process for forming a low-k material.

In accordance with another embodiment, the second electrically insulating layer 103″ may include or may be made of diamond. In this case, the second electrically insulating layer 103″ may be formed using any suitable process for forming a diamond layer or diamond-containing layer.

In accordance with another embodiment, the second electrically insulating layer 103″ may include or may be made of a laminate including an electrically insulating matrix material and a mechanically stabilizing material embedded in the electrically insulating matrix material, for example a fiber reinforced laminate material in accordance with an embodiment.

In accordance with an embodiment, the laminate of the second electrically insulating layer 103″ may include or may be made of the same material(s) as the laminate of the first electrically insulating layer 103′. In accordance with another embodiment, the laminates of the first and second electrically insulating layers 103′, 103″ may include or may be made of different materials. Alternatively or in addition, the second electrically insulating layer 103″ may be configured in accordance with one or more embodiments described herein.

The second electrically insulating layer 103″ may be formed using any suitable process to form a laminate.

The first electrically insulating layer 103′ and the second electrically insulating layer 103″ thus form a layer stack 103 that includes a plurality of electrically insulating layers.

In accordance with other embodiments, the layer stack 103 may include additional electrically insulating layers. That is, one or more additional electrically insulating layers may be formed over the second electrically insulating layer 103″. The individual layers may be formed consecutively and may be configured in a similar or the same manner as the first electrically insulating layer 103′ and/or second electrically insulating layer 103″.

FIG. 7D shows, in a schematic sectional side view 760, that an electrically conductive layer 204 may be formed over (for example, on) the layer stack 103, for example over the second electrically insulating layer 103″ of the layer stack 103 in accordance with the embodiment shown. The electrically conductive layer 204 may be optional. The electrically conductive layer 204 may include or may be made of any suitable electrically conductive material, for example metal or a metal alloy in accordance with an embodiment. The electrically conductive layer 204 may be formed by means of any suitable process, for example by means of any suitable deposition process (e.g. metal deposition process). The electrically conductive layer 204 may, for example, serve to electrically contact an electrical contact element located on the back side of a semiconductor chip (for example a back side metallization, e.g. a drain terminal of a power transistor) to be disposed thereon, see below.

FIG. 7E shows, in a schematic sectional side view 780, that a semiconductor chip 102 may be disposed over (for example, on) the electrically conductive layer 204 (if present, otherwise over (e.g. on) the layer stack 103, e.g. on the second electrically insulating layer 103″ of the layer stack 103). The semiconductor chip 101 may have a first side 102a and a second side 102b opposite the first side 102b. The first side 102a may, for example, be a front side of the semiconductor chip 102 and the second side 102b may, for example, be a back side of the semiconductor chip 102. The semiconductor chip 102 may, for example, be configured as a transistor chip having electrical contact elements located on its front side 102a and back side 102b, for example as a power transistor having a source terminal and a gate terminal located on the front side 102a and a drain terminal located on the back side 102b of the chip 102 (not shown). The electrical contact element located on the chip back side 102b (e.g. the drain terminal of a power transistor) may be contacted by the electrically conductive layer 204. The semiconductor chip 102 may, for example, further be configured in accordance with one or more embodiments described herein.

In accordance with further embodiments, additional components may be formed or provided such as, for example, one or more electrical connections (e.g. bond wires) between the semiconductor chip 102 and external terminals (e.g. pins) and/or additional chips, an encapsulation structure (e.g. mold compound), a heat sink, one or more additional chips, etc. (not shown).

It should be noted that, in accordance with some embodiments, the layer stack 103 shown in FIG. 7E may additionally be formed over parts of the second side (back side) 101b and/or over at least parts of one or more sidewalls of the carrier 101 (not shown).

In accordance with another embodiment, the layer sequence in the layer stack 103 may be reversed. In other words, the second electrically insulating layer 103″ may be formed before the first electrically insulating layer 103′ so that the electrically insulating layer 103″ may be disposed between the carrier 101 and the first electrically insulating layer 103′.

In accordance with another embodiment, the layer stack 103 may only include the first electrically insulating layer 103′.

One effect of forming a layer stack 103 having a plurality of individual electrically insulating layers 103′, 103″ may be that an improved electrical insulation may be achieved because it may be avoided that defects such as pin holes reach through the whole insulation, as will be described herein below in connection with FIG. 8A and FIG. 8B.

FIG. 8A shows a schematic sectional side-view of a layer stack 103 (also referred to as multi-insulation-layer stack) including a plurality of insulating layers 103′, 103″ in accordance with an embodiment. The layer stack 103 may be part of a semiconductor device in accordance with one or more embodiments described herein, for example a semiconductor device as shown and described in connection with one or more embodiments shown in the figures.

For purposes of illustration, only a first electrically insulating layer 103′ and a second electrically insulating layer 103″ are shown. However, in accordance with some embodiments, the layer stack 103 may include more than two electrically insulating layers. It has to be noted that, in accordance with some embodiments, the electrical insulation behavior of the layer stack 103 may be improved with increasing number of distinct electrically insulating layers.

In accordance with an embodiment, the electrically insulating layers (i.e. the first electrically insulating layer 103′ and the second electrically insulating layer 103″ in accordance with the embodiment shown) of the layer stack 103 may in each case include or be a laminate including an electrically insulating matrix material and a mechanically stabilizing material embedded in the matrix material. The electrically insulating layers 103′, 103″ may include or may be made of the same materials in accordance with an embodiment. Alternatively, the electrically insulating layers 103′, 103″ may include or may be made of different materials.

The electrically insulating layers 103′, 103″ may be formed as distinct layers, for example using two separate layer formation process steps (i.e. a first layer formation process step to form the first electrically insulating layer 103′ and a second layer formation process step to form the second electrically insulating layer 103″) in accordance with an embodiment. Thus, even in case that the electrically insulating layers 103′, 103″ include or are made of the same materials it may be possible that, since the electrically insulating layers 103′, 103″ are not formed as a single contiguous layer in one single process step, a distinct interface or interface region 801 may evolve between the adjacent layers 103′, 103″, as shown in FIG. 8A. At this interface or interface region 801, the two layers 103′, 103″ may have surface properties instead of bulk properties. For example, at the interface 801 each of the two adjacent layers 103′, 103″ may exhibit a molecular or atomic arrangement that is characteristic for its surface (instead of a molecular or atomic arrangement that is characteristic for its bulk). Illustratively, the interface or interface region 801 may represent a distinct “breaking point” in the layer stack 103.

As shown, one or more of the electrically insulating layers 103′, 103″ may have one or more defects 802 (e.g. pin holes) that may partially or completely reach through the respective layer. In the embodiment shown, each of the layers 103′, 103″ is shown to have a single defect 802 reaching through the entire layer 103′, 103″, as an example. However, as will be readily understood, the first electrically insulating layer 103′ and/or the second electrically insulating layer 103″ may have a different number of defects 802 (e.g. more than one, but also zero defects may be possible), and it may also be possible that one or more of the defects do not reach through the entire layer.

As shown, the defect 802 reaching through the first electrically insulating layer 103′ terminates at the interface 801, and the defect 802 reaching through the second electrically insulating layer 103″ also terminates at the interface 801. Since the electrically insulating layers 103′, 103″ are formed as distinct (in other words, separate) layers, the probability that the location of the defect 802 in the first electrically insulating layer 103′ matches the location of the defect 802 in the second electrically insulating layer 103″ is comparatively low. Thus, the probability that the defects 802 form a joined defect reaching through the entire layer stack 103 is also comparatively low. As will be understood, the probability of a defect reaching through the entire layer stack 103 will become ever smaller with increasing number of electrically insulating layers in the stack 103.

Thus, as shown in FIG. 8A, it may be avoided that defects (which may degrade the electrical insulation behavior) may reach through the entire layer stack 103.

FIG. 8B shows, as a comparison, an electrical insulation 803 formed by a single electrically insulating layer. The electrical insulation 803 may, for example, have the same total layer thickness as the layer stack 103 shown in FIG. 8A. As shown, a defect 802 (e.g. pin hole) may be formed in the electrical insulation 803. The defect 802 may reach through the entire thickness of the electrical insulation 803, as shown. The probability of a defect 802 reaching through the entire insulation 803 may be comparatively higher, compared to the layer stack 103 shown in FIG. 8A, as the insulation 803 is formed of a single (contiguous) layer. Thus, since the defect 802 reaches through the whole insulation 803, the electrical insulation behavior of the insulation 803 may be degraded. In order to achieve the same insulation performance as with the layer stack 103 shown in FIG. 8A, it may, for example, be necessary to increase the thickness of the electrical insulation 803 of FIG. 8B to reduce the probability that defects reach through the entire insulation 803. This may imply additional processing complexity and/or costs.

In accordance with various embodiments, a semiconductor device may include: a carrier; a semiconductor chip disposed over a first side of the carrier; a layer stack disposed between the carrier and the semiconductor chip or over a second side of the carrier opposite the semiconductor chip, or both, the layer stack including at least a first electrically insulating layer, the first electrically insulating layer containing a laminate having a first electrically insulating matrix material and a first mechanically stabilizing material embedded in the first electrically insulating matrix material . . . .

In various embodiments, the first electrically insulating matrix material and the first mechanically stabilizing material may be different materials.

In various embodiments, the first side of the carrier may be a front side of the carrier and the second side of the carrier may be a back side of the carrier.

In various embodiments, the carrier may include or may be made of an electrically conductive material.

In various embodiments, the electrically conductive material may include or may be a metal or a metal alloy.

In various embodiments, the carrier may be a metal carrier or a metal plate.

In various embodiments, the carrier may be a leadframe.

In various embodiments, the layer stack may be disposed over the first side of the carrier between the carrier and the semiconductor chip.

In various embodiments, the layer stack may be disposed over the second side of the carrier.

In various embodiments, the first electrically insulating matrix material may include or may be made of at least one material selected from a group of materials consisting of: a plastic material (e.g. a resin material, e.g. epoxy resin), an oxide material (e.g. a semiconductor oxide such as silicon oxide, or a metal oxide (e.g. alumina)), a nitride material (e.g. a semiconductor nitride such as silicon nitride, or a metal nitride (e.g. AlN)), a low-k material, or carbon (e.g. diamond).

In various embodiments, the first mechanically stabilizing material may include or may be made of at least one material selected from a group of materials consisting of: a fiber material (e.g. a glass fiber material), an oxide material (e.g. a semiconductor oxide such as silicon oxide, or a metal oxide (e.g. alumina)), a nitride material (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles).

In various embodiments, the semiconductor chip may be configured as a power semiconductor chip having at least one electrical contact element located on a side facing the carrier.

In various embodiments, the power semiconductor chip may include or may be a power transistor, e.g. a power MOSFET or a power IGBT in accordance with some embodiments.

In various embodiments, the first electrically insulating layer may have a layer thickness in the range from about 1 μm to about 1000 μm.

In various embodiments, the layer stack may further include a second electrically insulating layer disposed over the first electrically insulating layer.

In various embodiments, the second electrically insulating layer may include at least one material selected from a group of materials consisting of: an organic insulating material, an oxide material, a nitride material, a low-k material, diamond.

In various embodiments, the second electrically insulating layer may contain a laminate having an electrically insulating matrix material and a mechanically stabilizing material embedded in the electrically insulating matrix material.

In various embodiments, the first electrically insulating matrix material and the second electrically insulating matrix material may be the same material.

In various embodiments, the first electrically insulating matrix material and the second electrically insulating matrix material may be different materials.

In various embodiments, the second electrically insulating matrix material may include or may be made of at least one material selected from a group of materials consisting of: a plastic material (e.g. a resin material, e.g. epoxy resin), an oxide material (e.g. a semiconductor oxide such as silicon oxide, or a metal oxide (e.g. alumina)), a nitride material (e.g. a semiconductor nitride such as silicon nitride, or a metal nitride (e.g. AlN)), a low-k material, or carbon (e.g. diamond).

In various embodiments, the first mechanically stabilizing material and the second mechanically stabilizing material may be the same material.

In various embodiments, the first mechanically stabilizing material and the second mechanically stabilizing material may be different materials.

In various embodiments, the second mechanically stabilizing material may include or may be made of at least one material selected from a group of materials consisting of: a fiber material (e.g. a glass fiber material), an oxide material (e.g. a semiconductor oxide such as silicon oxide, or a metal oxide (e.g. alumina)), a nitride material (e.g. a semiconductor nitride such silicon nitride, or a metal nitride (e.g. AlN)), a low-k material, carbon (e.g. diamond, carbon nanotubes (CNT), graphene), or metal particles (e.g. Cu and/or Fe particles).

In various embodiments, the layer stack may include at least one additional electrically insulating layer.

In various embodiments, the at least one additional electrically insulating layer may contain a laminate having an electrically insulating matrix material and a mechanically stabilizing material embedded in the electrically insulating matrix material.

In various embodiments, a number of electrically insulating layers of the layer stack may be in the range from two to ten, for example in the range from two to five in accordance with some embodiments.

In various embodiments, the layer stack may have a total layer thickness in the range from about 1 μm to about 10000 μm.

In various embodiments, the semiconductor device may further include an encapsulation structure, wherein at least one of the carrier and the semiconductor chip may be at least partly covered by the encapsulation structure.

In various embodiments, the encapsulation structure may include or may be made of a mold compound.

In various embodiments, the semiconductor device may further include a heat sink coupled to at least one of the carrier and the layer stack.

In accordance with various embodiments, a semiconductor device may include: a carrier; a semiconductor chip disposed over a first side of the carrier; a layer stack disposed between the carrier and the semiconductor chip or over a second side of the carrier opposite the semiconductor chip, or both, the layer stack including at least a first electrically insulating layer and a second electrically insulating layer disposed over the first electrically insulating layer, the first electrically insulating layer containing a laminate having a first electrically insulating matrix material and a first mechanically stabilizing material embedded in the first electrically insulating matrix material, and the second electrically insulating layer containing a laminate having a second electrically insulating matrix material and a second mechanically stabilizing material embedded in the second electrically insulating matrix material.

In various embodiments, the first electrically insulating matrix material and the first mechanically stabilizing material may be different materials.

In various embodiments, the second electrically insulating matrix material and the second mechanically stabilizing material may be different materials.

In various embodiments, the first side of the carrier may be a front side of the carrier and the second side of the carrier may be a back side of the carrier.

In various embodiments, the carrier may include or may be made of an electrically conductive material.

In various embodiments, the electrically conductive material may include or may be a metal or a metal alloy.

In various embodiments, the carrier may be a metal carrier or a metal plate.

In various embodiments, the carrier may be a leadframe.

In various embodiments, the layer stack may be disposed over the first side of the carrier between the carrier and the semiconductor chip.

In various embodiments, the layer stack may be disposed over the second side of the carrier.

In various embodiments, at least one of the first electrically insulating matrix material and the second electrically insulating matrix material may include or may be made of at least one material selected from a group of materials consisting of: a plastic material (e.g. a resin material, e.g. epoxy resin), an oxide material (e.g. a semiconductor oxide such as silicon oxide, or a metal oxide (e.g. alumina)), a nitride material (e.g. a semiconductor nitride such as silicon nitride, or a metal nitride (e.g. AlN)), a low-k material, or carbon (e.g. diamond).

In various embodiments, the first electrically insulating matrix material and the second electrically insulating matrix material may include or may be the same material.

In various embodiments, the first electrically insulating matrix material and the second electrically insulating matrix material may include or may be different materials.

In various embodiments, at least one of the first mechanically stabilizing material and the second mechanically stabilizing material may include or may be made of at least one material selected from a group of materials consisting of: a fiber material (e.g. a glass fiber material), an oxide material (e.g. a semiconductor oxide such as silicon oxide, or a metal oxide (e.g. alumina)), a nitride material (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles).

In various embodiments, the first mechanically stabilizing material and the second mechanically stabilizing material may include or may be the same material.

In various embodiments, the first mechanically stabilizing material and the second mechanically stabilizing material may include or may be different materials.

In various embodiments, the semiconductor chip may be configured as a power semiconductor chip having at least one electrical contact element located on a side facing the carrier.

In various embodiments, the power semiconductor chip may include or may be a power transistor, e.g. a power MOSFET or a power IGBT in accordance with some embodiments.

In various embodiments, at least one of the first electrically insulating layer and the second electrically insulating layer may have a layer thickness in the range from about 1 μm to about 1000 μm.

In various embodiments, the layer stack may further include at least one additional electrically insulating layer disposed over the second electrically insulating layer, the at least one additional electrically insulating layer containing a laminate having an electrically insulating matrix material and a mechanically stabilizing material embedded in the electrically insulating matrix material.

In various embodiments, the electrically insulating matrix material of the at least one additional electrically insulating layer and the mechanically stabilizing material of the at least one additional electrically insulating layer may include or may be different materials.

In various embodiments, the electrically insulating matrix material of the at least one additional electrically insulating layer may include or may be made of at least one material selected from a group of materials consisting of: a plastic material (e.g. a resin material, e.g. epoxy resin), an oxide material (e.g. a semiconductor oxide such as silicon oxide, or a metal oxide (e.g. alumina)), a nitride material (e.g. a semiconductor nitride such as silicon nitride, or a metal nitride (e.g. AlN)), a low-k material, or carbon (e.g. diamond).

In various embodiments, the electrically insulating matrix material of the at least one additional electrically insulating layer may include or may be the same material as the first electrically insulating matrix material or the second electrically insulating matrix material, or both.

In various embodiments, the electrically insulating matrix material of the at least one additional electrically insulating layer may be different from the first electrically insulating matrix material or the second electrically insulating matrix material or both.

In various embodiments, the mechanically stabilizing material of the at least one additional electrically insulating layer may include or may be made of at least one material selected from a group of materials consisting of: a fiber material (e.g. a glass fiber material), an oxide material (e.g. a semiconductor oxide such as silicon oxide, or a metal oxide (e.g. alumina)), a nitride material (e.g. a semiconductor nitride such as silicon nitride, or a metal nitride (e.g. AlN)), a low-k material, carbon (e.g. diamond, carbon nanotubes (CNT), graphene), or metal particles (e.g. Cu and/or Fe particles).

In various embodiments, the mechanically stabilizing material of the at least one additional electrically insulating layer may include or may be the same material as the first mechanically stabilizing material or the second mechanically stabilizing material, or both.

In various embodiments, the mechanically stabilizing material of the at least one additional electrically insulating layer may be different from the first mechanically stabilizing material or the second mechanically stabilizing material, or both.

In various embodiments, a number of electrically insulating layers of the layer stack may be in the range from two to ten, for example in the range from two to five in accordance with some embodiments.

In various embodiments, the layer stack may have a total layer thickness in the range from about 2 μm to about 10000 μm.

In various embodiments, the semiconductor device may further include an encapsulation structure, wherein at least one of the carrier and the semiconductor chip may be at least partly covered by the encapsulation structure.

In various embodiments, the encapsulation structure may include or may be made of a mold compound.

In various embodiments, the semiconductor device may further include a heat sink coupled to at least one of the carrier and the layer stack.

In accordance with various embodiments, a semiconductor device may include: a carrier; a semiconductor chip disposed over a first side of the carrier; a layer stack disposed between the carrier and the semiconductor chip or over a second side of the carrier opposite the semiconductor chip, or both, the layer stack including a plurality of electrically insulating layers, each electrically insulating layer containing a laminate having an electrically insulating matrix material and a mechanically stabilizing material embedded in the electrically insulating matrix material.

In various embodiments, the carrier may be electrically conductive.

In various embodiments, the semiconductor chip may be configured as a power chip including at least one electrical contact element on a side facing the carrier.

In accordance with various embodiments, a semiconductor device may include: a carrier; a semiconductor chip mounted on the carrier; a layer stack disposed between the carrier and the semiconductor chip or over a side of the carrier opposite the semiconductor chip, or both, the layer stack including a plurality of electrically insulating layers, each of the electrically insulating layers containing a laminate having an electrically insulating matrix material and a reinforcement material embedded in the electrically insulating matrix material.

In accordance with various embodiments, a semiconductor device may include: a carrier; a semiconductor chip mounted on the carrier; a layer stack disposed between the carrier and the semiconductor chip or over a side of the carrier opposite the semiconductor chip, or both, the layer stack including a plurality of electrically insulating layers, each of the electrically insulating layers containing a fiber reinforced laminate material.

In accordance with various embodiments, a module may be provided, the module including: a carrier; a semiconductor chip mounted on the carrier; an insulation layer stack disposed between the carrier and the semiconductor chip or on a side of the carrier opposite to the semiconductor chip, or both, wherein the insulation layer stack includes a plurality of electrically insulating layers, each of the layers containing a laminate having an electrically insulating matrix material and a mechanically stabilizing material embedded in the electrically insulating matrix material.

In accordance with various embodiments, a method of fabricating a semiconductor device may include: disposing a semiconductor chip over a first side of a carrier; disposing a layer stack over the first side of the carrier between the carrier and the semiconductor chip or over a second side of the carrier opposite the semiconductor chip, or both, the layer stack including at least a first electrically insulating layer, the first electrically insulating layer containing a laminate having a first electrically insulating matrix material and a first mechanically stabilizing material embedded in the first electrically insulating matrix material.

In various embodiments, the carrier may be electrically conductive.

In various embodiments, disposing the layer stack may include forming the first electrically insulating layer over the first side or second side, or both sides, of the carrier and then forming the second electrically insulating layer over the first electrically insulating layer.

In various embodiments, the semiconductor chip may be configured as a power semiconductor chip including at least one electrical contact element located on a side facing the carrier.

In various embodiments, the layer stack may include at least one additional electrically insulating layer containing a laminate having an electrically insulating matrix material and a mechanically stabilizing material embedded in the electrically insulating matrix material, and disposing the layer stack may further include forming the at least one additional electrically insulating layer over the second electrically insulating layer.

In accordance with various embodiments, a semiconductor device may include: a carrier; a semiconductor chip disposed over a first side of the carrier; a layer stack disposed between the carrier and the semiconductor chip or over a second side of the carrier opposite the semiconductor chip, or both, the layer stack including a plurality of electrically insulating layers, each electrically insulating layer containing a laminate having an electrically insulating matrix material and a mechanically stabilizing material embedded in the electrically insulating matrix material.

In accordance with various embodiments, a semiconductor device may include: a carrier; a semiconductor chip mounted on the carrier; a layer stack disposed between the carrier and the semiconductor chip or over a side of the carrier opposite the semiconductor chip, or both, the layer stack including a plurality of electrically insulating layers, each of the electrically insulating layers containing a laminate having an electrically insulating matrix material and a reinforcement material embedded in the electrically insulating matrix material.

In accordance with various embodiments, a semiconductor device may include: a carrier; a semiconductor chip mounted on the carrier; a layer stack disposed between the carrier and the semiconductor chip or over a side of the carrier opposite the semiconductor chip, or both, the layer stack including a plurality of electrically insulating layers, each of the electrically insulating layers containing a fiber reinforced laminate material.

In accordance with various embodiments, a method of fabricating a semiconductor device may include: disposing a semiconductor chip over a first side of a carrier; disposing a layer stack over the first side of the carrier between the carrier and the semiconductor chip or over a second side of the carrier opposite the semiconductor chip, or both, the layer stack including at least a first electrically insulating layer and a second electrically insulating layer disposed over the first electrically insulating layer, the first electrically insulating layer containing a laminate having a first electrically insulating matrix material and a first mechanically stabilizing material embedded in the first electrically insulating matrix material, and the second electrically insulating layer containing a laminate having a second electrically insulating matrix material and a second mechanically stabilizing material embedded in the second electrically insulating matrix material.

In the following, exemplary features and potential effects of exemplary embodiments described herein are discussed.

In accordance with various embodiments, a fully insulated power package with high thermal performance may be provided.

The current rating of power devices such as, for example, power MOSFETs (metal-oxide-semiconductor field effect transistors) or power IGBTs (insulated-gate bipolar transistors), in power packages may generally be limited by the following equation:

$${I}_{max}^{2} = \frac{Δ T}{{R}_{on} {R}_{th}} ,$$

where Iₘₐₓ is the maximum current rating, ΔT=T_{junction}−T_{ambient} (i.e. temperature difference between temperature at the junction and ambient temperature), Rₒₙ is the electrical resistance and Rₜₕ is the thermal resistance of the device.

In accordance with various embodiments, a multi-insulation-layer-approach for semiconductor devices such as, for example, power packages may be provided that may have a reduced thermal resistance (Rₜₕ) so that the maximum current rating Iₘₐₓ may be increased compared to conventional fully insulated power packages, for example compared to fully insulated power packages using only mold compound for full insulation, in which the full limitation may be limited by mold compound behavior and the molding process.

In accordance with various embodiments, encapsulation of a chip (e.g. power chip) with encapsulation material and full insulation of the chip may be realized using separate materials and/or separate processes. For example, encapsulation of the chip may be realized using a conventional chip encapsulation material (e.g. mold compound) while full insulation may be realized using a dedicated insulation material (e.g. a reinforced laminate in accordance with various embodiments) and process. Thus, both the encapsulation process (e.g. molding process) and the insulation process may be optimized. The terms “full insulation” or “fully insulated”, as used herein, may for example be understood to include a back side isolation of a power package.

In accordance with various embodiments, a multi-insulation-layer stack including a plurality of electrically insulating layers may be disposed between a chip to be electrically insulated (e.g. a power chip) and a carrier (e.g. a die pad of a leadframe) of a semiconductor device. Such an arrangement may also be referred to as internal insulation.

In accordance with various embodiments, a multi-insulation-layer stack including a plurality of electrically insulating layers may be disposed on a side of the carrier that is opposite to the side, on which the chip is mounted. In other words, the chip may be disposed over a first side (e.g. top side) of the carrier while the multi-insulation-layer stack may be disposed over a second side (e.g. bottom side) of the carrier that is opposite the first side. Such an arrangement may also be referred to as external insulation.

In accordance with some embodiments, a semiconductor device may include both an internal insulation and an external insulation.

In accordance with various embodiments, a defect density, such as a number of pin holes per area, in the insulation may be reduced because the probability of generating a pin hole that reaches through the whole insulation (i.e. through the layer stack of electrically insulating layers) may decrease with increasing number of layers in the layer stack. In other words, the higher the number of layers in the layer stack, the lower the probability of occurrence of pin holes reaching through the whole layer stack. The reason may be seen in that, even if a number of pin holes exist in two adjacent layers of the layer stack, the probability that a pin hole in one of the two layers matches in position with a pin hole in the other one of the two layers will be comparatively low so that the probability that the two pin holes form a joined pin hole reaching through the two layers will also be comparatively low. With increasing number of layers, the probability that pin holes in all of the individual layers match in position and thus form a joined pin hole reaching through the entire layer stack will become ever lower.

One effect of a reduced number of defects (e.g. pin holes) in the insulation may be seen in an increased blocking capability of the multi-layer insulation compared to conventional single-layer insulations. As a result, the same blocking capability as in conventional single-layer insulations may be achieved with a smaller total layer thickness in the multi-layer insulation in accordance with various embodiments, or, if the same total layer thickness as in a conventional single-layer insulation is used for the multi-layer insulation, a blocking capability may be achieved that is higher than a blocking capability of the conventional single-layer insulation.

In accordance with various embodiments described herein, the electrically insulating layers of a multi-insulation-layer stack may include or may be made of a laminate containing an electrically insulating matrix material (for example a plastic material, e.g. a resin material such as epoxy resin) and a mechanically stabilizing material or component (for example a fiber material) embedded in the matrix material. In accordance with some embodiments, the laminates used for the electrically insulating layers of the stack may, for example, be configured in a similar manner and/or may include or be made of similar materials as applied for a circuit board (e.g. printed circuit board (PCB)). Effects or features of laminates may be or may include 3D (three-dimensional): formability or moldability of a laminate; processability of a laminate on various different surfaces (e.g. with regard to temperature budget or adhesion); realization of semi-finished products (layer does not have to be produced completely); modifiability of material properties.

In accordance with other embodiments, one or more of the electrically insulating layers may include or may be made of other insulating materials, such as for example, oxides such as e.g. metal oxides (e.g. aluminum oxide, copper oxide, or other suitable metal oxides), semiconductor oxides such as e.g. silicon oxide or other suitable oxides, nitrides such as e.g. metal nitrides (e.g. aluminum nitride or other suitable metal nitrides), semiconductor nitrides such as e.g. silicon nitride or other suitable nitrides, or organic insulating materials. In this case, one or more of the electrically insulating layers could, for example, be formed by means of any suitable deposition process, including e.g. spray-processes (e.g. plasma-spray processes), laminating processes and other suitable deposition processes.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A semiconductor device, comprising:
a carrier;
a semiconductor chip disposed over a first side of the carrier;
a layer stack disposed between the carrier and the semiconductor chip or over a second side of the carrier opposite the semiconductor chip, or both, the layer stack comprising at least a first electrically insulating layer, the first electrically insulating layer comprising a laminate comprising a first electrically insulating matrix material and a first mechanically stabilizing material embedded in the first electrically insulating matrix material.

2. The semiconductor device of claim 1,
wherein the carrier comprises an electrically conductive material.

3. The semiconductor device of claim 2,
wherein the carrier comprises a metal plate.

4. The semiconductor device of claim 1,
wherein the first electrically insulating matrix material comprises at least one material selected from a group of materials consisting of:
a polymer material;
an oxide material;
a nitride material;
a low-k material;
carbon.

5. The semiconductor device of claim 1,
wherein the first mechanically stabilizing material comprises at least one material selected from a group of materials consisting of:
a fiber material;
an oxide material;
a nitride material;
a low-k material;
carbon;
metal particles.

6. The semiconductor device of claim 1,
wherein the semiconductor chip is configured as a power semiconductor chip comprising at least one electrical contact element located on a side facing the carrier.

7. The semiconductor device of claim 1,
wherein the first electrically insulating layer has a layer thickness in the range from about 1 μm to about 1000 μm.

8. The semiconductor device of claim 1,
the layer stack further comprising a second electrically insulating layer disposed over the first electrically insulating layer.

9. The semiconductor device of claim 8,
wherein the second electrically insulating layer comprises at least one material selected from a group of materials consisting of:
an organic insulating material;
an oxide material;
a nitride material;
a low-k material;
diamond.

10. The semiconductor device of claim 8, the second electrically insulating layer comprising a laminate comprising a second electrically insulating matrix material and a second mechanically stabilizing material embedded in the second electrically insulating matrix material.

11. The semiconductor device of claim 10,
wherein the first electrically insulating matrix material and the second electrically insulating matrix material are the same material.

12. The semiconductor device of claim 10,
wherein the first electrically insulating matrix material and the second electrically insulating matrix material are different materials.

13. The semiconductor device of claim 10,
wherein the second electrically insulating matrix material comprises at least one material selected from a group of materials consisting of:
a polymer material;
an oxide material;
a nitride material;
a low-k material.

14. The semiconductor device of claim 10,
wherein the first mechanically stabilizing material and the second mechanically stabilizing material are the same material.

15. The semiconductor device of claim 10,
wherein the first mechanically stabilizing material and the second mechanically stabilizing material are different materials.

16. The semiconductor device of claim 10,
wherein the second mechanically stabilizing material comprises at least one material selected from a group of materials consisting of:
a fiber material;
an oxide material;
a nitride material;
a low-k material;
carbon;
metal particles.

17. The semiconductor device of claim 8,
the layer stack further comprising at least one additional electrically insulating layer.

18. The semiconductor device of claim 17,
the at least one additional electrically insulating layer comprising a laminate comprising an electrically insulating matrix material and a mechanically stabilizing material embedded in the electrically insulating matrix material.

19. The semiconductor device of claim 1,
wherein the layer stack has a total layer thickness in the range from about 1 μm to about 10000 μm.

20. The semiconductor device of claim 1, further comprising an encapsulation structure,
wherein at least one of the carrier and the semiconductor chip is at least partly covered by the encapsulation structure.

21. The semiconductor device of claim 20,
wherein the encapsulation structure comprises a mold compound.

22. The semiconductor device of claim 1, further comprising a heat sink coupled to at least one of the carrier and the layer stack.

23. A semiconductor device, comprising:
a carrier;
a semiconductor chip disposed over a first side of the carrier;
a layer stack disposed between the carrier and the semiconductor chip or over a second side of the carrier opposite the semiconductor chip, or both, the layer stack comprising a plurality of electrically insulating layers, each electrically insulating layer comprising a laminate comprising an electrically insulating matrix material and a mechanically stabilizing material embedded in the electrically insulating matrix material.

24. The semiconductor device of claim 23,
wherein the carrier is electrically conductive.

25. The semiconductor device of claim 23,
wherein the semiconductor chip is configured as a power chip comprising at least one electrical contact element located on a side facing the carrier.

26. A method of fabricating a semiconductor device, the method comprising:
disposing a semiconductor chip over a first side of a carrier;
disposing a layer stack over the first side of the carrier between the carrier and the semiconductor chip or over a second side of the carrier opposite the semiconductor chip, or both, the layer stack comprising at least a first electrically insulating layer, the first electrically insulating layer comprising a laminate comprising a first electrically insulating matrix material and a first mechanically stabilizing material embedded in the first electrically insulating matrix material.
